(19) United States
(12) Patent Application Publication
(10) Pub. No.: US 2012/0037889 A1
(43) Pub. Date: Feb. 16, 2012

(54) ORGANIC ELECTROLUMINESCENCE ELEMENT, DISPLAY DEVICE AND ILLUMINATION DEVICE

(75) Inventors: Tatsuo Tanaka, Kanagawa (JP); Hiroshi Kita, Tokyo (JP); Eisaku Katoh, Tokyo (JP); Rie Katakura, Tokyo (JP)

(73) Assignee: KONICA MINOLTA HOLDINGS, INC., Tokyo (JP)

(21) Appl. No.: 13/132,685

(22) PCT Filed: Dec. 3, 2009
(86) PCT No.: PCT/JP2009/070321

§ 371 Date: Sep. 14, 2011

(30) Foreign Application Priority Data
Dec. 8, 2008 (JP) 2008-311884

(51) Int. Cl. H01L 51/54

(52) U.S. Cl. 257/40; 257/E51.028

(57) ABSTRACT

Provided is an organic electroluminescence element having an anode, a cathode and an organic compound layer sandwiched between the anode and the cathode, provided that the organic compound layer containing at least a phosphorescence dopant and a polymer which contains a partial structure represented by Formula (1), and a terminal end of the polymer is end-capped, wherein the phosphorescence dopant is a metal complex containing a ligand composed of a 5 or six membered aromatic hydrocarbon ring or a 5 or six membered aromatic heterocyclic group which is bonded to a five membered nitrogen containing aromatic heterocyclic group: Formula (1)

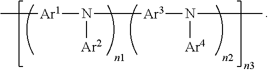

### TECHNICAL FIELD

The present invention relates to an organic electroluminescence element, a display device and a lighting device using the same.

### BACKGROUND

In the past, there have been carried out development focusing on the structure of the compound contained in an organic electroluminescence element (hereafter, it is also called as an organic EL element) as one of the means to improve the lifetime of an organic EL element. As a result, some materials which can be employed for practical use have been found out.

However, small alternation of structure, such as introduction of a substituent, has caused large effect on various characteristics, such as a lifetime and luminescent properties. And moreover, since prediction was difficult, the issue which should be resolved was left behind.

Using a polymer as a construction material of an organic EL element is already known widely (for example, refer to patent documents 1 and 2), and it is recognized as a useful technique.

Moreover, an organic EL element using a polymer material having the specific weight average molecular weight was introduced as a well-known technique (for example, refer to patent document 3.)

Based on these patent documents, it was thought that a very useful element could be obtained when a polymer and a phosphorescence dopant were used as materials for an organic EL element and development was taken place. It became clear that there was a new problem which was not listed in the patent documents.

That is, when a polymer and a phosphorescence dopant were used as materials for an organic EL element, there was caused a problem of increasing a driving voltage after driving the obtained organic EL element for a long time. It was supposed that this composition had deteriorated effect on an element lifetime, and the solution of these problems is demanded.

### PRIOR ART TECHNICAL DOCUMENTS

### Patent Documents

Patent document 1: Japanese Patent Application Publication (JP-A) No. 10-308280
Patent document 2: Japanese Translation of PCT International Application Publication No. 2001-527102
Patent document 3: JP-A No. 2004-292782

### SUMMARY OF THE INVENTION

### Problems to be Solved by the Invention

An object of the present invention is to provide an organic electroluminescence element, a display device and a lighting device, which do not show increase of driving voltage even after prolonged driving and realize a long life.

### Means to Solve the Problems

An object of the present invention described above has been achieved by the following constitutions.

1. An organic electroluminescence element comprising an anode, a cathode and an organic compound layer sandwiched between the anode and the cathode, provided that the organic compound layer comprises at least a phosphorescence dopant and a polymer which contains a partial structure represented by Formula (1), and a terminal end of the polymer is end-capped,

wherein the phosphorescence dopant is a metal complex containing a ligand composed of a 5 or six membered aromatic hydrocarbon ring or a 5 or six membered aromatic heterocyclic group which is bonded to a five membered nitrogen containing aromatic heterocyclic group.

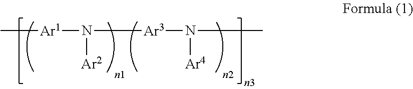

In Formula, Ar¹ and Ar³ each independently represent an arylene group which may have a substituent, and Ar¹ and Ar³ each may be bonded through a joint group. Ar² and Ar⁴ each independently represent an aryl group or an aromatic heterocyclic group which may have a substituent. n1 and n2 are integer of 0 to 2, provided that n1 and n2 are not simultaneously set to be 0. n3 is an integer of 10 to 1,000.

2. The organic electroluminescence element described in the aforesaid item 1,

wherein the phosphorescence dopant is a compound represented by Formula (D-1).

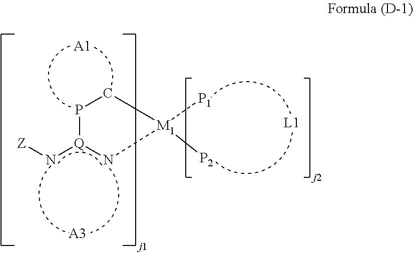

In Formula, P and Q each represent a carbon atom or a nitrogen atom, and A1 represents an atomic group which forms an aromatic hydrocarbon ring or an aromatic heterocyclic group together with P—C. A3 is an atomic group which forms an aromatic heterocyclic group together with N-Q-N. P₁-L1-P₂ represents a bidentate ligand, provided that P₁ and P₂ each independently represent a carbon atom, a nitrogen atom, or an oxygen atom. L1 represents an atomic group which forms a bidentate ligand together with P₁ and P₂. j1 is an integer of 1 to 3, and j2 is an integer of 0 to 2, provided that the sum of j1 and j2 is 2 or 3. M₁ represents a transition metal element of Group 8 to Group 10 in the periodic table. Z represents a substituent.

3. The organic electroluminescence element described in the aforesaid items 1 or 2,

wherein the polymer containing the partial structure represented by Formula (1) contains a partial structure represented by Formula (2).

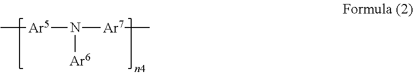

In Formula, Ar⁵ and Ar⁷ each independently represent an arylene group which may have a substituent, Ar⁶ represents an aryl group or an aromatic heterocyclic group which may have a substituent. n4 is an integer of 10 to 1,000.

4. The organic electroluminescence element described in the aforesaid items 1 or 2,

wherein the polymer containing the partial structure represented by Formula (1) contains a partial structure represented by Formula (3).

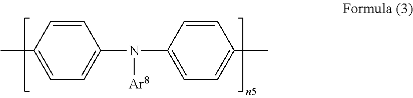

In Formula, Ar⁸ represents an aryl group or an aromatic heterocyclic group which may have a substituent. n4 is an integer of 10 to 1,000.

5. The organic electroluminescence element described in any one of the aforesaid items 1 to 4,

wherein the polymer containing the partial structure represented by Formula (1) has a weight average molecular weight of 50,000 to 500,000 as a polystyrene conversion value.

6. The organic electroluminescence element described in any one of the aforesaid items 1 to 5,

wherein the phosphorescence dopant is a blue phosphorescence dopant

7. The organic electroluminescence element described in any one of the aforesaid items 1 to 6,

wherein at least two organic compound layers are prepared by film making with a wet process.

8. The organic electroluminescence element described in any one of the aforesaid items 1 to 6, wherein the organic electroluminescence element emits a white light.
9. A lighting device comprising the organic electroluminescence element of any one of the aforesaid items 1 to 8.
10. A display device comprising the organic electroluminescence element of any one of the aforesaid items 1 to 8.

### EFFECT OF THE INVENTION

By the present invention, it has been achieved to provide an organic electroluminescence element, a blue light emitting element, a white light emitting element, a display device and a lighting device, which do not show increase of driving voltage even after prolonged driving and realize a long life.

### BRIEF DESCRIPTION OF THE DRAWINGS

FIG. 1 is a schematic drawing of a lighting device.

FIG. 2 is a schematic drawing of a lighting device.

FIG. 3 is a schematic drawing to show an example of a display device composed of an organic EL element.

FIG. 4 is a schematic drawing of a display section A.

### EMBODIMENTS TO CARRY OUT THE INVENTION

The inventors of the present invention worked on various solutions to resolve the above-mentioned problems. As a result, it was discovered that and a longer lifetime was realized by suppressing a voltage increase by using a polymer having a larger molecular weight than the polymer having been investigated until now. Thus, the present invention was achieved.

It is recognized that these are findings which became clear only after investigated carefully the new filed which has not been carried out in prior art, and this finding is a very important technology.

By using a polymer which has a partial structure represented by any one of Formulas (1) to (3) concerning the present invention, it became possible to form a layer which is highly solvent resistive and applicable to a wet process and it became possible to form a layer of high smoothness. Also, it became possible to produce a laminated constitution by a wet process.

For example, when it was produced a layer containing a lower molecular weight oligomer with the same repetition unit as the polymer having a partial structure represented by any one of Formulas (1) to (3) of the present invention, it was revealed followings. When a wet process was used at the time of producing the organic compound layer (it is also called an organic layer) which was adjacent to the layer containing this oligomer, there was high possibility for the oligomer to dissolve into the adjacent organic compound layer. As a result, there was a trouble that it became difficult to form a film with a wet process.

On the other hand, there is another method to form a layer in which after forming a thin film of a polymerizable low molecule compound with a wet process, the formed thin film is made to polymerize with ultraviolet radiation or heat to insolubilize to solvent, then adjacent layer is produced with a wet process. This method has the following problems. It is highly possible that the membrane is given a damage with light or heat, and it becomes difficult to secure surface smoothness and to obtain an element which satisfies the target properties.

Moreover, it was also found out that the luminescence efficiency of the organic electroluminescence element was improved by using together the phosphorescence luminescence dopant of the present invention and the polymer having a partial structure represented by any one of Formulas (1) to (3) of the present invention.

Conventionally, the dope concentration of the dopant used in a light emission layer is in the range of up to about 10%. An optimum point of the dope concentration will exist in the range. However, in the organic EL element of the present invention, there exists an optimum point of the dope concentration with respect to luminescence efficiency and luminescence lifetime in the higher range of 10% to 40%. Moreover, it was found out that higher luminescence efficiency can be achieved than using a conventional dopant.

However, when the dope concentration of the dopant is increased and a light emission layer is produced by a wet process, the contamination of the dopant to the adjacent layer which has been produced in advance will occur, and this will cause deterioration of lifetime and luminescence efficiency.

The organic electroluminescence element of the present invention uses an organic compound layer containing a phosphorescence dopant and a polymer containing a partial structure represented by any one of Formulas (1) to (3) of the present invention as a constituting layer. By this layer composition, it became possible to control the contamination between the layers generated at the time of wet process application, and to realize optimization of the dope concentration, and as a result, it became possible to provide an organic electroluminescence element with high luminescence efficiency.

### <Partial Structure Represented by any One of Formulas (1) to (3)>

Partial structures represented by any one of Formulas (1) to (3) will be described.

In Formulas (1) to (3), examples of an arylene group represented by Ar¹, Ar³, Ar⁵, and Ar⁷, and which may have a substituent are: a phenylene group, and a biphenyl diyl group (such as [1,1′-biphenyl]-4,4′-diyl group, 3,3′-biphenyl diyl group, and 3,6-biphenyl diyl group). These groups may have a substituent such as a lower alkyl group or a lower alkoxyl group. Further, Ar¹, Ar³, Ar⁵, and Ar⁷ each may be bonded through a joint group. Examples of a joint group are as follows.

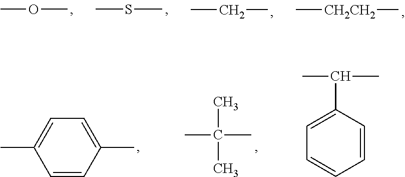

These are a divalent group. And “Ar¹, Ar³, Ar⁵, and Ar⁷ each are bonded through a joint group” indicates as below when the joint group is —O— or —S—.

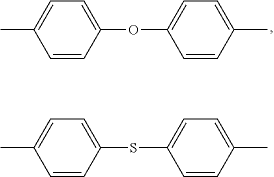

The bonding above is an example.

Preferable group of Ar¹, Ar³, Ar⁵, and Ar⁷ are as follows.

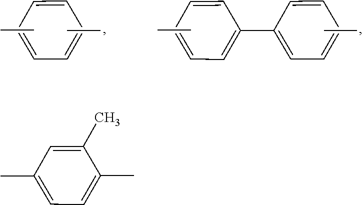

These are examples.

Ar², Ar⁴, Ar⁶, and Ar⁸ each independently represent an aryl group (such as a phenyl group or a biphenyl group) or a hetero cyclic group (such as a thienyl group or a furyl group), which may have a substituent. These groups may have a substituent such as an alkyl group or an alkoxyl group.

Preferably, Ar², Ar⁴, Ar⁶, and Ar⁸ each independently represent a phenyl group, or a phenyl group having a substituent of an alkyl group or an alkoxyl group.

n1 represents an integer of 0 to 2, and more preferably n1 represents an integer of 0 to 1. n2 represents an integer of 0 to 2, and more preferably n2 represents an integer of 0 to 1. Provided that n1 and n2 are not simultaneously set to be 0. n3, n4 and n5 each independently represent an integer of 10 to 1,000, and more preferably they represent an integer of 20 to 1,000.

Examples of a substituent which can be substituted on the group represented by Formulas (1) to (3) include: an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group); a cycloalkyl group (for example, a cyclopentyl group, and a cyclohexyl group); an alkenyl group (for example, a vinyl group and an allyl group); an alkynyl group (for example, an ethynyl group and a propargyl group); an aromatic hydrocarbon ring group (also called an aromatic carbon ring or an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenantolyl group, an indenyl group, a pyrenyl group, and a biphenyryl group); an aromatic heterocyclic group (for example, a pyridyl group, a pyrazyl group, a pyrimidinyl group, a triazyl group, a furyl group, a pyrrolyl group, an imidazolyl group, a benzoimidazolyl group, a pyrazolyl group, a pyradinyl group, a triazolyl group (for example, 1,2,4-triazole-1-yl group and 1,2,3-triazole-1-yl group), an oxazolyl group, a benzoxazolyl group, a thiazolyl group, an isooxazolyl group, an isothiazolyl group, a furazanyl group, a thienyl group, a quinolyl group, a benzofuryl group, a dibenzofuryl group, a benzothienyl group, a dibenzothenyl group, an indolyl group, a carbazolyl group, an azacarbazolyl group (indicating a ring structure in which one or more of the carbon atoms constituting the carbazolyl group are replaced with nitrogen atoms), a quinoxalinyl group, a pyridazinyl group, a triazinyl group, a quinazolinyl group, a phthalazinyl group); a heterocyclic group (for example, a pynolidyl group, an imidazolidyl group, a morpholyl group, and an oxazolidyl group); an alkoxyl group (for example, a methoxy group, an ethoxy group, a propyloxy group, a pentyloxy group, an hexyloxy group, an octyloxy group, and a dodecyloxy group); a cycloalkoxy group (for example, a cyclopentyloxy group and a cyclohexyloxy group); an aryloxy group (for example, a phenoxy group and a naphthyloxy group); an alkylthio group (for example, a methylthio group, an ethylthio group, a propylthio group, a pentylthio group, a hexylthio group, an octylthio group, and a dodecylthio group); a cycloalkylthio group (for example, a cyclopentylthio group and a cyclohexylthio group); an arylthio group (for example, a phenylthio group and a naphthylthio group); an alkoxycarbonyl group (for example, a methyloxycarbonyl group, an ethyloxycarbonyl group, a butyloxycarbonyl group, an octyloxycarbonyl group, and a dodecyloxycarbonyl group); an aryloxycarbonyl group (for example, a phenyloxycarbonyl group and a naphthyloxycarbonyl group); a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group); an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group); an acyloxy group (for example, an acetyloxy group, an ethylcarbonyloxy group, a butylcarbonyloxy group, an octylcarbonyloxy group, a dodecylcarbonyloxy group, and a phenylcarbonyloxy group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, and a naphthylcarbonylamino group); a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, and a 2-pyridylaminocarbonyl group); a ureido group (for example, a methylureido group, an ethylureido group, a pentylureido group, a cyclohexylureido group, an octylureido group, a dodecylureido group, a phenylureido group, a naphthylureido group, and a 2-oyridylaminoureido group); a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group); an alkylsulfonyl group (for example, a methylsulfonyl group, an ethylsulfonyl group, a butylsulfinyl group, a cyclohexylsulfonyl group, a 2-ethylhexylsulfonyl group, and a dodecylsulfonyl group, an arylsulfonyl group or a heteroarylsulfonyl group (for example, a phenylsulfonyl group, a naphthylsulfonyl group, and a 2-pyridylsulfonyl group); an amino group (for example, an amino group, an ethylamino group, a dimethylamino group, a butylamino group, a cyclopentylamino group, a dodecylamino group, an anilino group, a naphthylamino group, and a 2-pyridylamino group); a cyano group; a nitro group; a hydroxyl group; a mercapto group; a silyl group (for example, a trimethylsilyl group, a triisopropylsilyl group, a triphenylsilyl group, and a phenyldiethylsilyl group) and a phosphono group.

Moreover, these substituents may be further substituted with the above-mentioned substituent. Further, a plurality of these substituents may combine with each other to form a ring.

As for the polymer which has a partial structure represented by any one of Formulas (1) to (3) concerning the present invention, it is characterized that the terminal end of the polymer is end-capped.

Here, the end cap is described in details in patent document 2, and the outline is as follows.

By adding an end-capping agent (compound which stops polymer growth) during a polymer synthesizing reaction, polymerization is controlled and it becomes possible to restrict further growth of a polymer chain. Therefore, when an end-capping agent is added excessively (for example, in a step which should stop polymerization), further growth of a polymer chain (and/or a polymer network when the polymer has a branch or a cross linkage bond) will be controlled substantially (for example, substantially stopped).

Namely, an end-capping agent will give a terminal group to the polymer end so that coupling reaction does not substantially take place (for example, with other polymer precursor and/or other part of the polymer) under the polymerization condition. This terminal group will end-cap the polymer and block the portion where the polymer chain grows if it is not end-capped. Thus, it will function to substantially reduce (preferably, stop) the possibility of further polymerization.

In the compound concerning the present invention, it is preferable that from 60% to substantially all of the polymerizable portions are blocked with at least one terminal substituent. More preferably, substantially all polymerizable portions are blocked (as an example).

In another still more preferable case, about 60% to about 90% of these portions are blocked. About the examples of an end capping agent, there can be cited the examples listed in patent document 2 and patent document 3.

Although an object of the end cap treatment concerning the present invention is retardation of the polymerization reaction by adding an end capping agent during a polymerization reaction, it is also one of the important objects to inactivate the reactive site remained in the polymer terminals after a polymerization reaction.

That is, an extensive improvement in lifetime of an organic EL element is expected by inactivating reactive substituents which remained in the polymer terminals at the time of the termination of a polymerization reaction of homo-coupling, cross coupling, etc., such as halogen, borate, an amino group, and a halogenated metal, by end cap treatment.

Examples of an end cap include: a hydrogen atom, an alkyl group (for example, a methyl group, an ethyl group, and a butyl group), aryl groups (for example, a phenyl group and a tolyl group), a hetero aryl group (for example, a thienyl group and a pyridyl group), a disubstituted amino group (for example, the diethylamino group, and a diphenylamino group), a trisubstituted silyl group (for example, a trimethyl silyl group a triphenyl silyl group).

As a specific method of performing an end cap treatment, there can be cited the followings as preferable examples: to add an end capping agent during the reaction or after termination of the reaction; to make reduction using hydrogenation, a Grignard reagent, or an alkylated metal such as butyl lithium.

The content of halogen at the polymer terminal after performing the end cap treatment is preferably below 1% (1,000 ppm), and more preferably it is 100 ppm or less, from the viewpoint of emission lifetime of the organic EL element.

Hereafter, examples of a partial structure represented by any one of Formulas (1) to (3) of the present invention are given. However, the present invention is not limited to these.

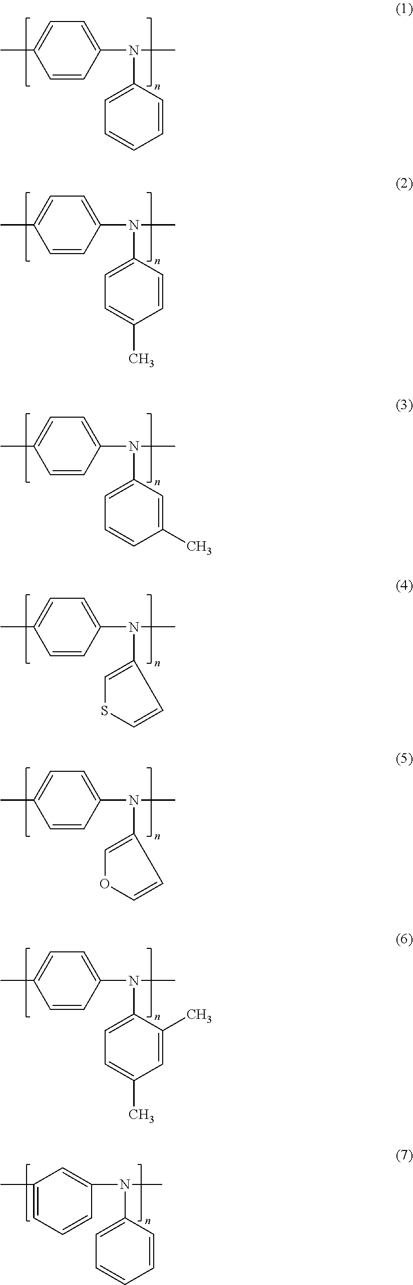

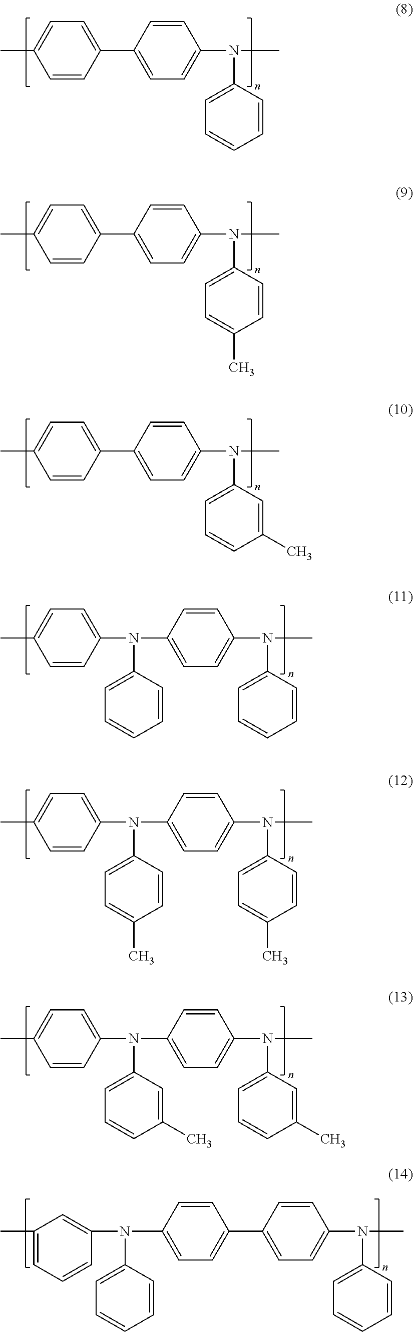

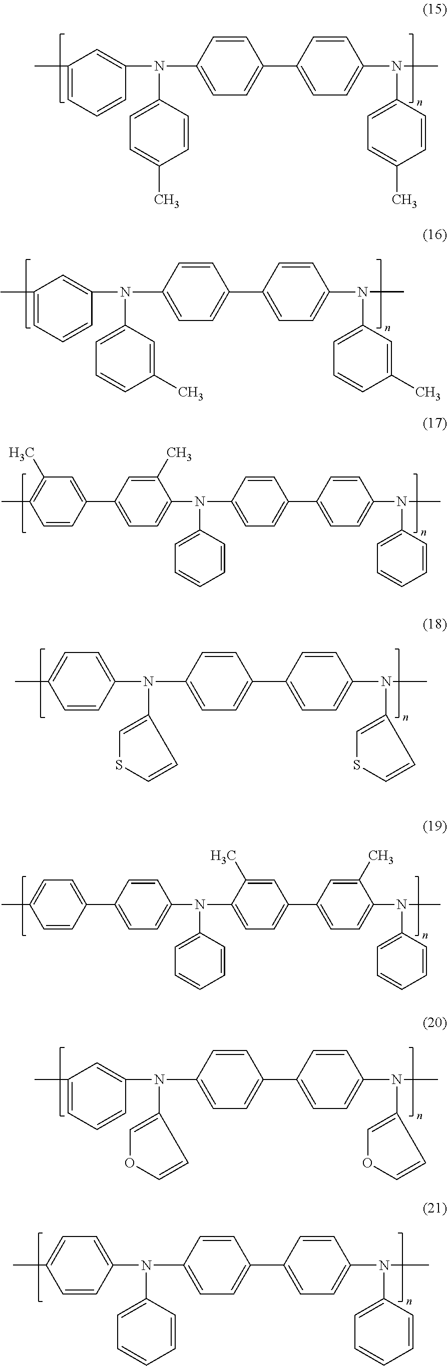

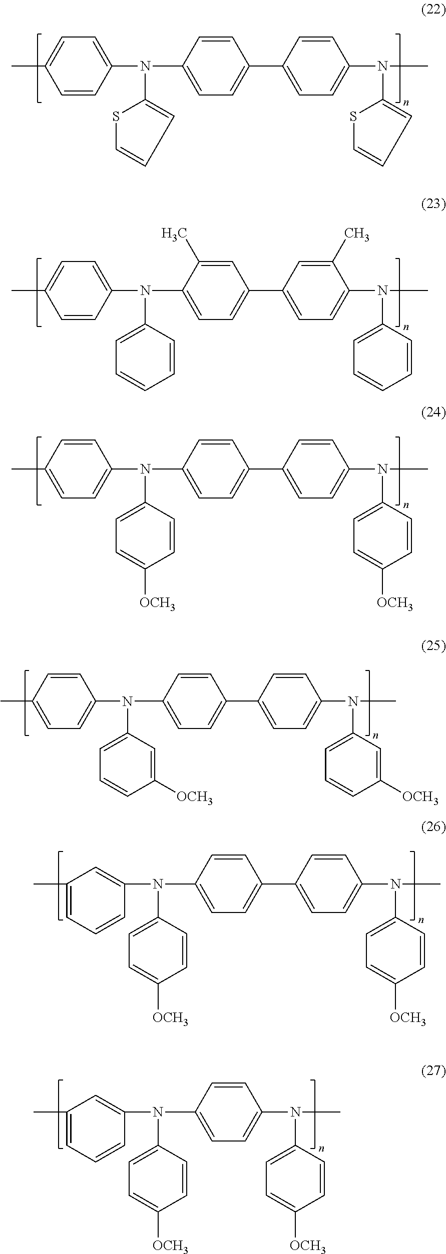

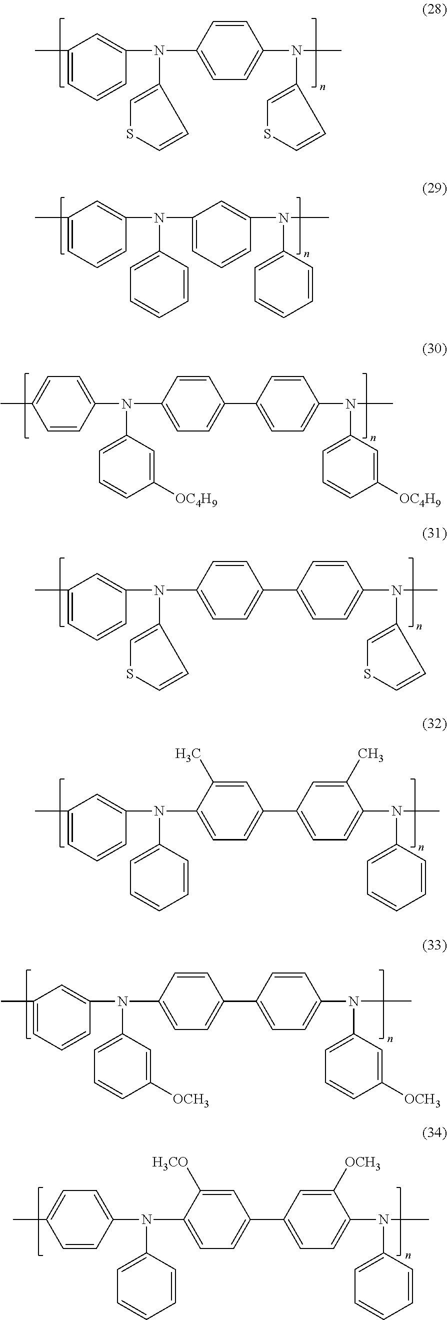

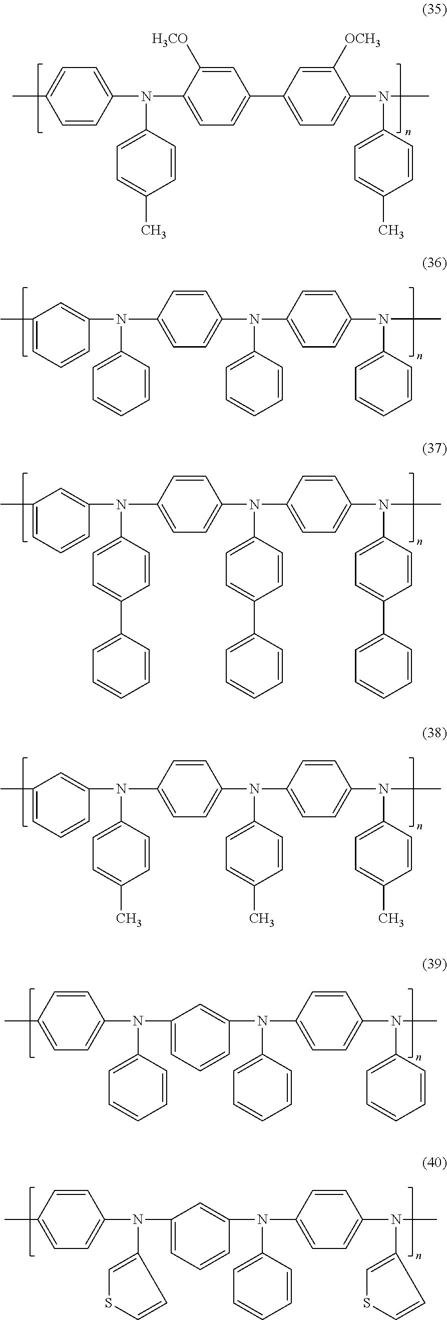

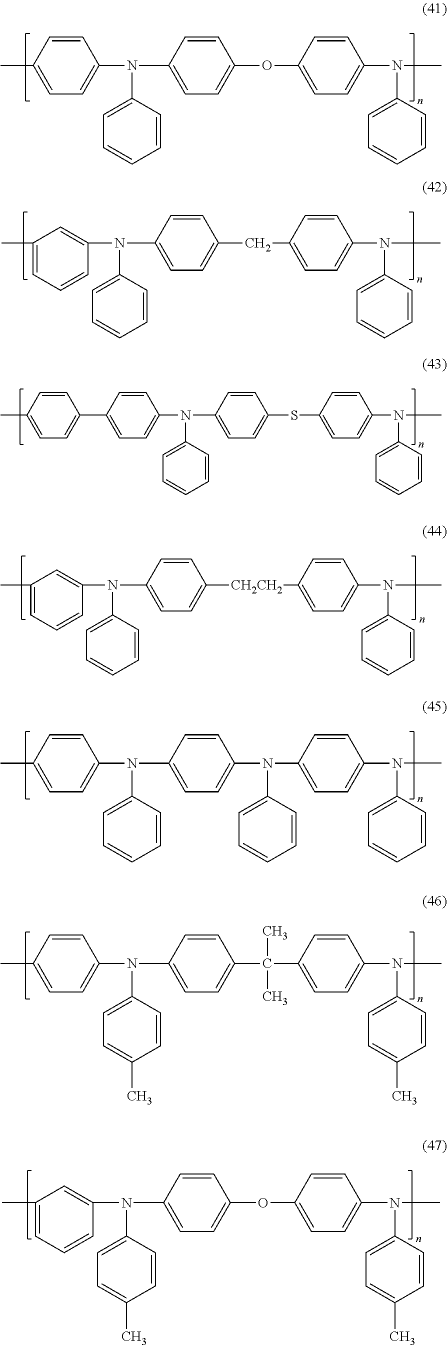

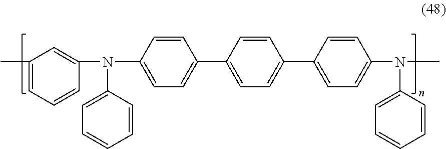

Hereafter, examples of a polymer containing a partial structure represented by any one of Formulas (1) to (3) of the present invention are given. However, the present invention is not limited to these.

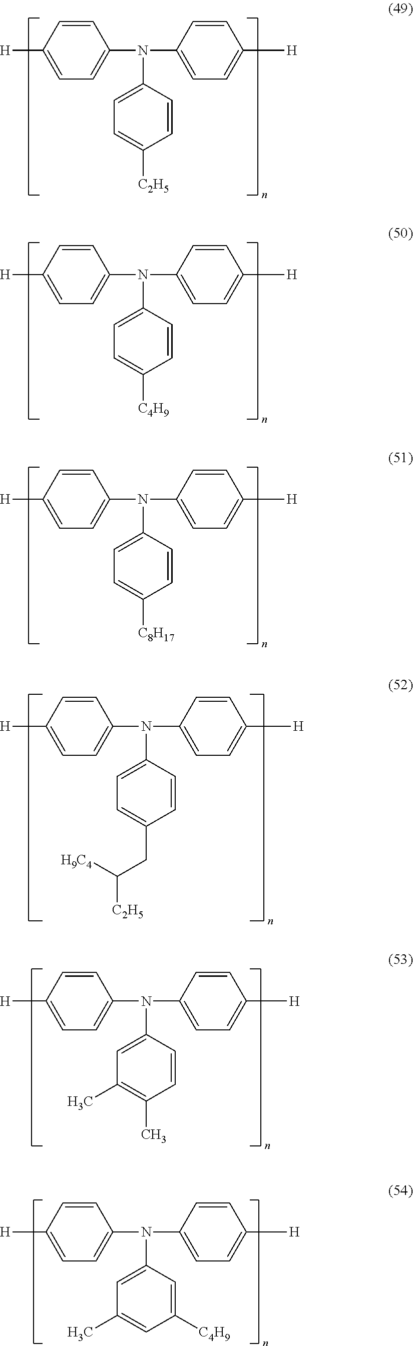

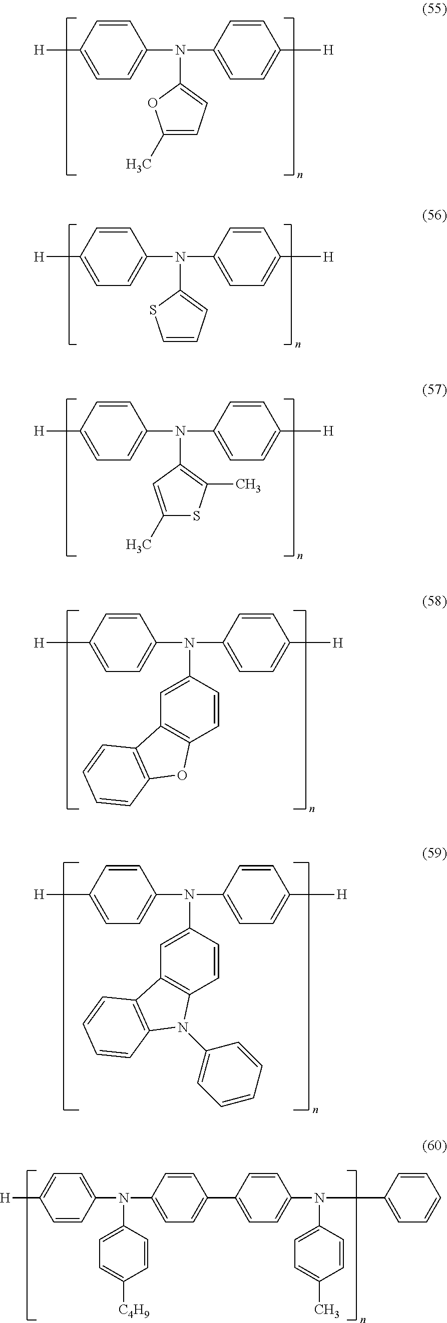

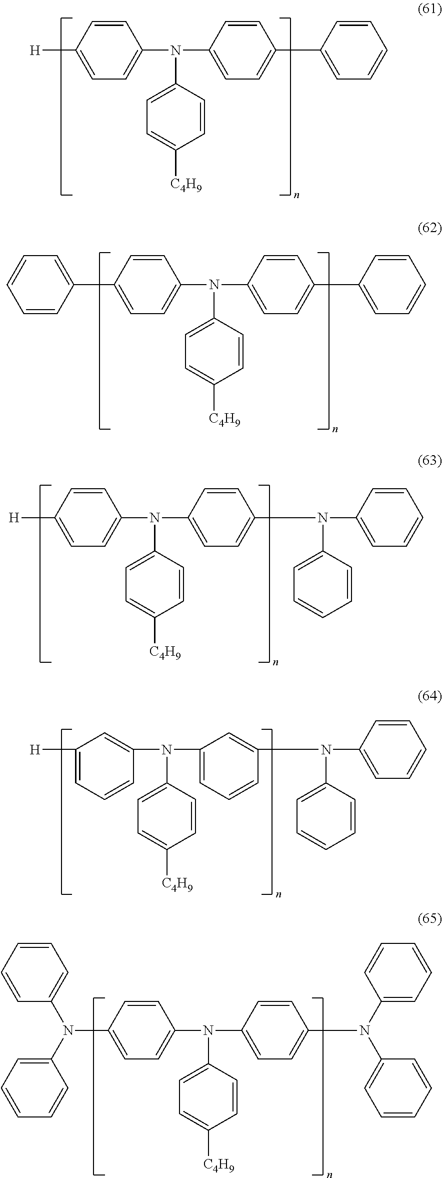

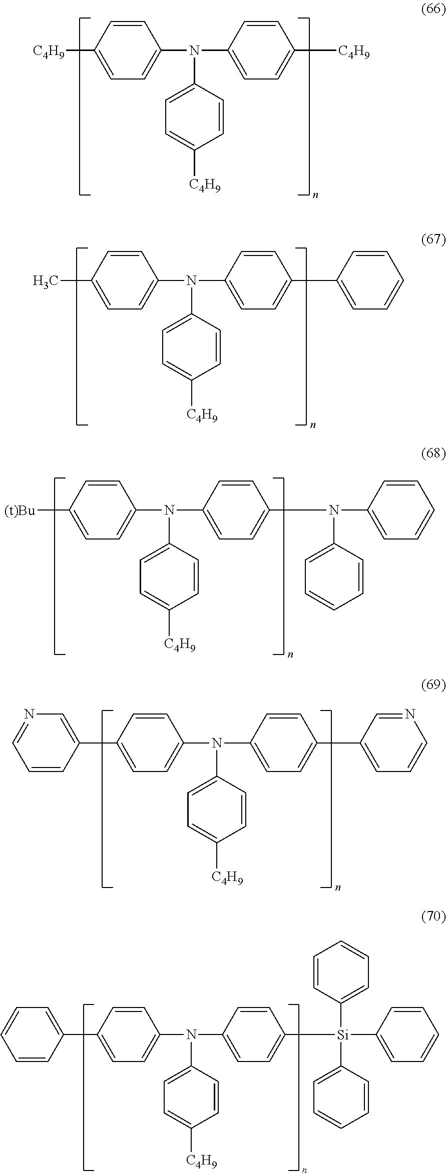

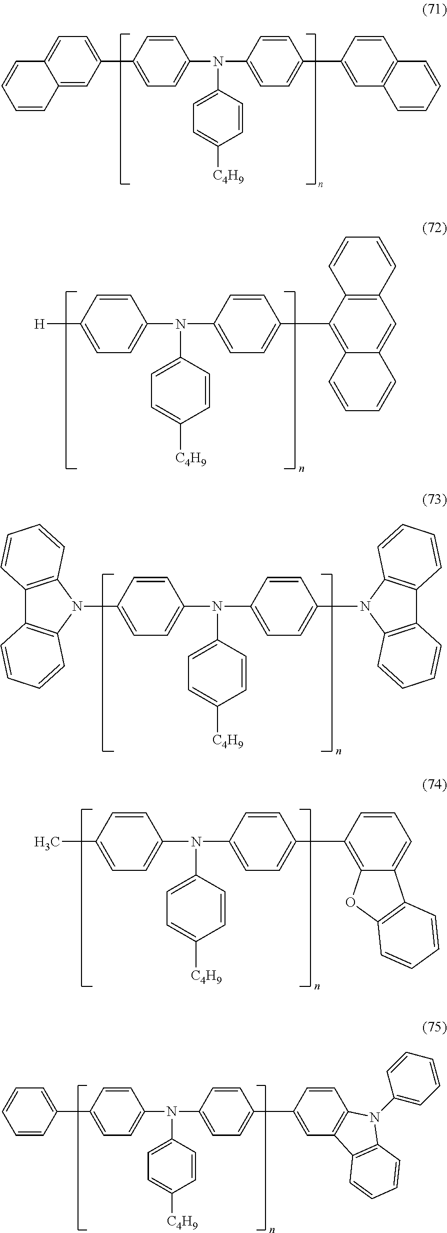

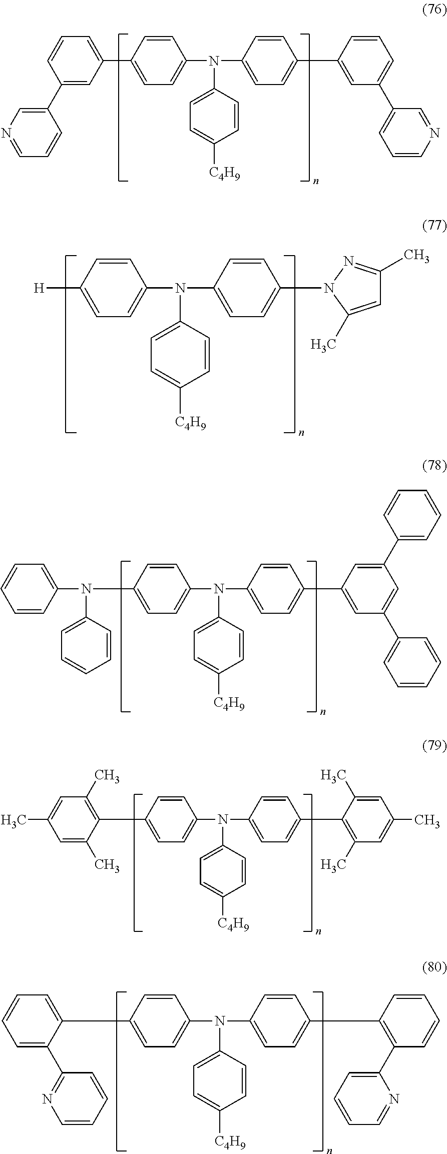

In addition, the above-mentioned n represents degree of polymerization, and it represents an integer of 10 to 1,000.

A polymer containing a partial structure represented by any one of Formulas (1) to (3) can be prepared by the well-known method described in, such as Makromol. Chem. 193, page 909 (1992).

Here, synthetic examples of a polymer containing a partial structure represented by any one of Formulas (1) to (3) of the present invention are given. However, the present invention is not limited to these.

First, as a synthetic example of an exemplified compound (50), there is shown below synthesis of Compounds 50a to 50d in which a weight average molecular weight and a molecular weight distribution are differ with each other.

<Synthesis of Exemplified Compound 50a>

### Synthetic Example

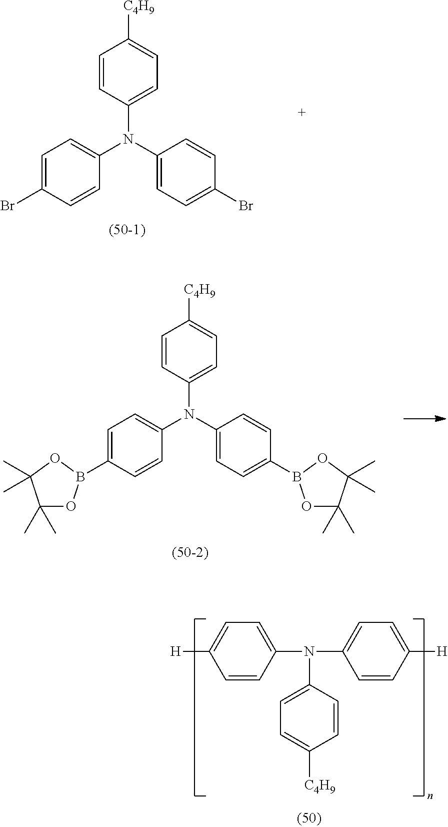

15.0 g of Compound 50-1 and 18.0 g of Compound 50-2 were dissolved in 200 ml of toluene, then under a nitrogen gas, were added 1.0 g of Aliquat 336 and 30 ml of 2 mol/L sodium hydrogencarbonate solution. This mixture was vigorously stirred, and was heated to reflux for 2 hours. Then, after added 1 g of bromobenzene, the mixture was heated for 5 hours. The reaction solution was cooled to 60° C., and it was added gently to a mixture solution of 3 L of methanol and 300 ml of pure water while stirring.

The produced precipitated material was filtered, and it was washed repeatedly with methanol and pure water, then it was dried in a vacuum oven at 60° C. for 10 hours to obtain Exemplified compound 50a (yield: 19.0 g weight average molecular weight: 5,000; and molecular weight distribution: 2.2).

The structure of exemplified compound 50a was confirmed using ¹H-NMR and ¹³C-NMR etc.

<Synthesis of Exemplified Compounds 50b, 50c and 50d>

Compound 50b (weight average molecular weight: 55,000; and molecular weight distribution: 2.0) was prepared in the same manner as above except that the reaction time was changed from 2 hours to 10 hours; Compound 50c (weight average molecular weight: 80,000; and molecular weight distribution: 1.9) was prepared in the same manner as above except that the reaction time was changed from 2 hours to 20 hours; and Compound 50d (weight average molecular weight: 150,000; and molecular weight distribution: 1.9) was prepared in the same manner as above except that the reaction time was changed from 2 hours to 50 hours.

Each structure of exemplified compound 50b, 50c, and 50d was confirmed using ¹H-NMR and ¹³C-NMR etc.

### <Synthesis of Exemplified Compound 62>

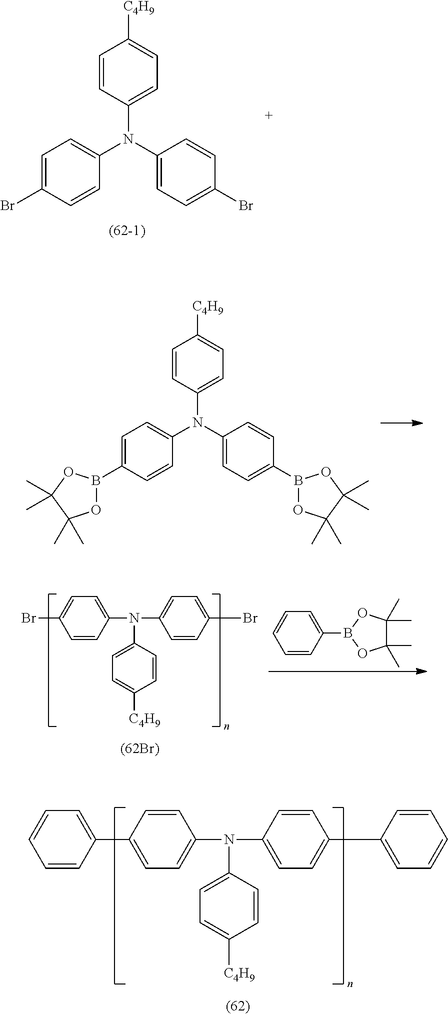

22.0 g of Compound 62-1 and 18.0 g of Compound 62-2 were dissolved in 200 ml of toluene, then under a nitrogen gas, were added 1.0 g of Aliquat 336 and 30 ml of 2 mol/L sodium hydrogencarbonate solution to prepare a mixture.

This mixture was vigorously stirred, and was heated to reflux for 22 hours. The obtained reaction solution was cooled to 60° C., and it was added gently to a mixture solution of 3 L of methanol and 300 ml of pure water while stirring.

The precipitated material was filtered, and it was washed repeatedly with methanol and pure water, then it was dried in a vacuum oven at 60° C. for 10 hours to obtain Compound 62Br (yield: 18.0 g; weight average molecular weight: 8,000; and molecular weight distribution: 2.3).

Subsequently, 10 g of Compound 62Br and 1 g of pinacol phenylboronate were dissolved in 200 ml of toluene, then under a nitrogen gas, were added 1.0 g of Aliquat 336 and 30 ml of 2 mol/L sodium hydrogencarbonate solution. This mixture was vigorously stirred, and was heated to reflux for 10 hours.

This reaction solution was cooled to 60° C., and it was added gently to a mixture solution of 2 L of methanol and 200 ml of pure water while stirring. The precipitated material was filtered, and it was washed repeatedly with methanol and pure water, then it was dried in a vacuum oven at 60° C. for 10 hours to obtain Compound 62 (yield: 9.8 g; weight average molecular weight: 8,000; and molecular weight distribution: 2.2).

It is preferable that the polymer containing a partial structure represented by any one of Formulas (1) to (3) incorporates little contamination of a low molecular weight component or a heavy metal and that its molecular weight distribution is small from the viewpoint of luminescent efficiency and a lifetime of the element.

Specifically, it is preferable that a content of an organic compound component having a weight average molecular weight of 1,000 or less is not more than 1%, further, it is preferable that a content of an organic compound component having a weight average molecular weight of 1,000 or less is not more than 1%.

It is preferable that the polymer containing a partial structure represented by any one of Formulas (1) to (3) has a weight average molecular weight in the range of 50,000 to 500,000, more preferably in the range of 70,000 to 100,000.

Moreover, a molecular weight distribution (Mw/Mn) is preferably 3 or less, more preferably, it is 2.5 or less.

It is preferable that the content of a heavy metal (for example, Pd, Cu and Pt) in the polymer containing a partial structure represented by any one of Formulas (1) to (3) is 500 ppm or less, more preferably it is 50 ppm or less.

Further, there will be described a molecular weight (a number average molecular weight (Mn), a weight average molecular weight (Mw), and a molecular weight distribution of a polymer containing a partial structure represented by any one of Formulas (1) to (3) of the present invention.

Measurement of the weight average molecular weight (Mw) and the number average molecular weight (Mn) of the polymer containing a partial structure represented by any one of Formulas (1) to (3) concerning the present invention can be performed by using GPC (gel permeation chromatography) employing THF (tetrahydrofuran) as a column solvent.

Specifically, it is performed as follows: adding 1 ml of THF (having subjected to deaeration treatment) to 1 mg of sample and fully dissolving the sample by stirring with a magnetic stirrer at a room temperature; after treating with a membrane filter having a pore size of 0.45 μm to 0.50 μm, the solution is injected to a GPC (gel permeation chromatography) apparatus.

Measurement conditions of GPC were as follows: to stabilize the column at 40° C., and to draw THF (tetrahydrofuran) at a flow rate of 1 ml per minute, then to measure by injecting 100 μl of sample solution having a content of 1 mg/ml.

It is preferable to use by combining commercial polystyrene gel columns a column. Preferable combinations are, for example: a combination of Shodex GPC KF-801, 802, 803, 804, 805, 806, and 807 (made by Showa Denko, Co., Ltd.), or a combination of TSKgel G1000H, G2000H, G3000H, G4000H, G5000H, G6000H, G7000H, and TSK guard column (made by TOSOH Corporation).

As a detector, a refractive index detector (RI detector) or UV detector is preferably used.

The determination of a molecular weight of a sample is computed based on a molecular weight distribution derived from a calibration curve created with monodisperse polystyrene standard particles. It is preferable to use about ten points of polystyrene for producing a calibration curve.

In the present invention, the determination of molecular weight was performed under the following measurement conditions.

### (Measurement Conditions)

Apparatus: TOSOH high speed GPC apparatus, HLC-8220GPC

Columns: TOSOH TSKgel Super HM-M

Detector: RI and/or UV; eluent flow rate: 0.6 ml/minute

Sample concentration: 0.1 mass %

Amount of sample: 100 μl

Calibration curve: Prepared using standard polystyrene; calibration curve was prepared by using 13 samples of STK standard polystyrene (made by TOSOH Corporation) having a molecular weigh of 1,000,000 to 500; and this calibration curve was used to calculate the molecular weight. As for 13 samples, it is preferable that these are selected having an equal intervals with each other.

### <Compounds Represented by Formula (D-1)>

In Formula (D-1), examples of an aromatic hydrocarbon ring formed by A1 with P—C are: a benzene ring, a biphenyl ring, a naphthalene ring, an azulene ring, an anthracene ring, a phenanthrene ring, a pyrene ring, a chrysene ring, a naphthacene ring, a triphenylene ring, an o-terphenyl ring, a m-terphenyl ring, a p-terphenyl ring, an acenaphthene ring a coronene ring a fluorene ring, a fluoanthrene ring a naphthacene ring, a pentacene ring, a perylene ring, a pentaphene ring, a picene ring a pyrene ring a pyranthrene ring and an anthraanthrene ring. These rings may further have a substituent.

In Formula (D-1), examples of an aromatic heterocyclic ring formed by A1 with P—C are: a furan ring, a thiophene ring, an oxazole ring, a pyrrole ring, a pyridine ring, a pyridazine ring a pyrimidine ring, a pyrazine ring, a triazine ring, a benzimidazole ring, an oxadiazole ring, a triazole ring, an imidazole ring, a pyrazole ring a thiazole ring, an indole ring a benzimidazole ring, a benzothiazole ring a benzoxazole ring, a quinoxaline ring, a quinazoline ring, a phthalazine ring a carbazole ring, a carboline ring, and a diazacarbazole ring.

Here, “a diazacarbazole ring” indicates a ring structure in which at least one of the carbon atoms constituting the carboline ring is replaced with a nitrogen atom). These rings may further have a substituent.

Examples of a substituent for the aforesaid aromatic hydrocarbon ring and the aforesaid aromatic heterocyclic ring can be cited the same substituent which may be substituted on the aforesaid Formulas (1) to (3).

In Formula (D-1), examples of an aromatic heterocyclic ring formed by A3 with N-Q-N are: an imidazole ring, a triazole ring, a tetrazole ring a benzimidazole ring a thiadiazole ring an oxadiazole ring, a pyrimidine ring, and a purine ring.

A preferable structure each formed by A1 and A3 is a phenyl imidazole structure.

In Formula (D-1), Z represents a substituent. Preferable examples thereof are the same substituents which can be substituted on Formulas (1) to (3)

In Formula (D-1), as a bidentate ligand represented by P₁-L1-P₂, there can be used various known ligands. Examples thereof are: ligands (such as a halogen ligand, preferably a chlorine ligand, a nitrogen containing hetero cyclic ligand such as bipyridyl and phenanthroline, and a diketone ligand) which are described in H. Yersin, “Photochemistry and Photophysics of Coordination Compounds”, Springer-Verlag (1987); and Akio Yamamoto, “Organo Metallic Chemistry—basis and application” Shokabo (1982).

One type of ligand may be used for the compound represented by Formula (D-1) concerning the present invention, and two or more types may be used. The number of the ligands in a complex is preferably 1 to 3 kinds, more preferably it is 1 or 2 kinds, and still more preferably, it is one kind.

In Formula (D-1), iridium and platinum are cited as preferable transition metal elements of Group 8 to Group 10 in the periodic table (it is called simply as “a transition metal”) represented by M₁.

Examples of a compound concerning the present invention represented by Formula (D-1) are shown hereafter. However, the present invention is not limited to these.

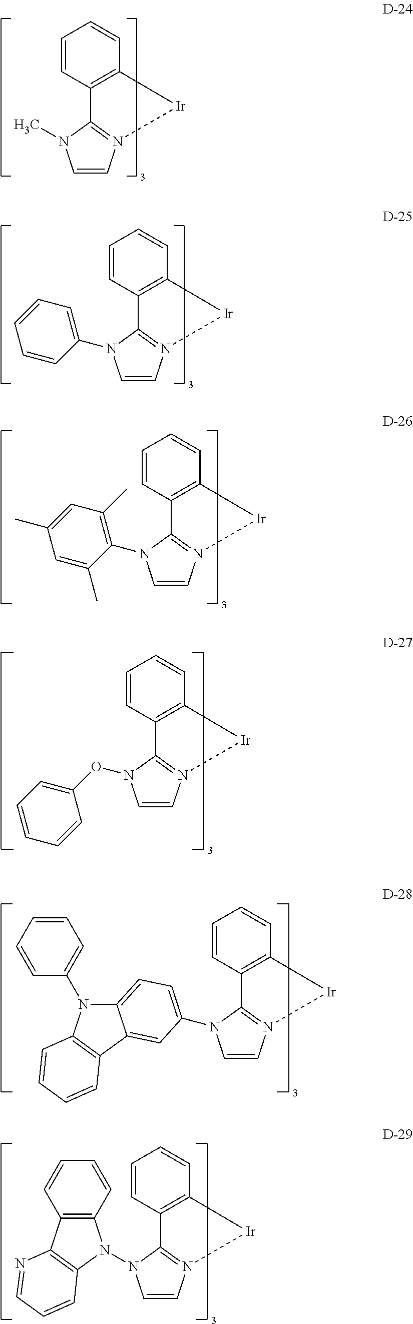

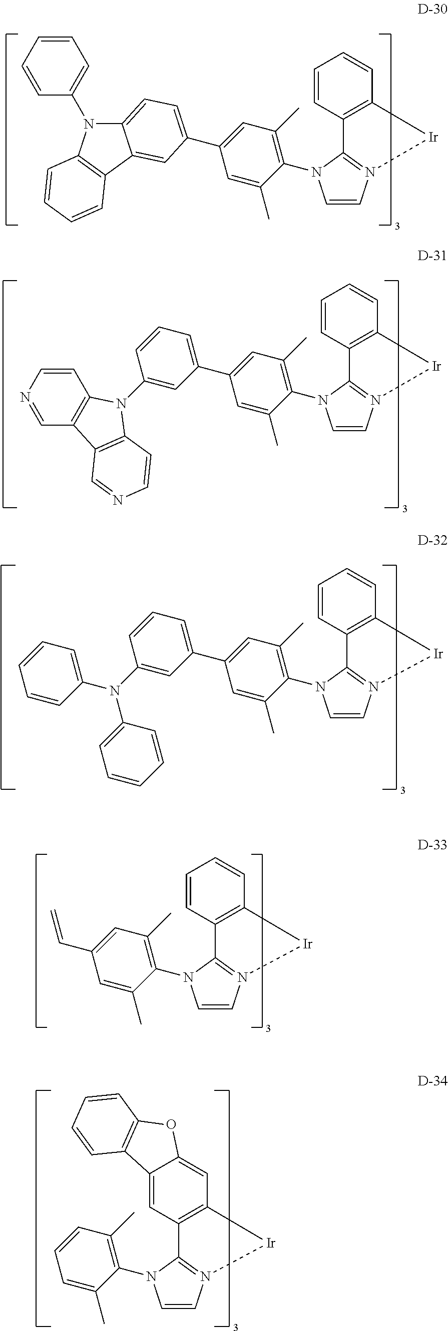

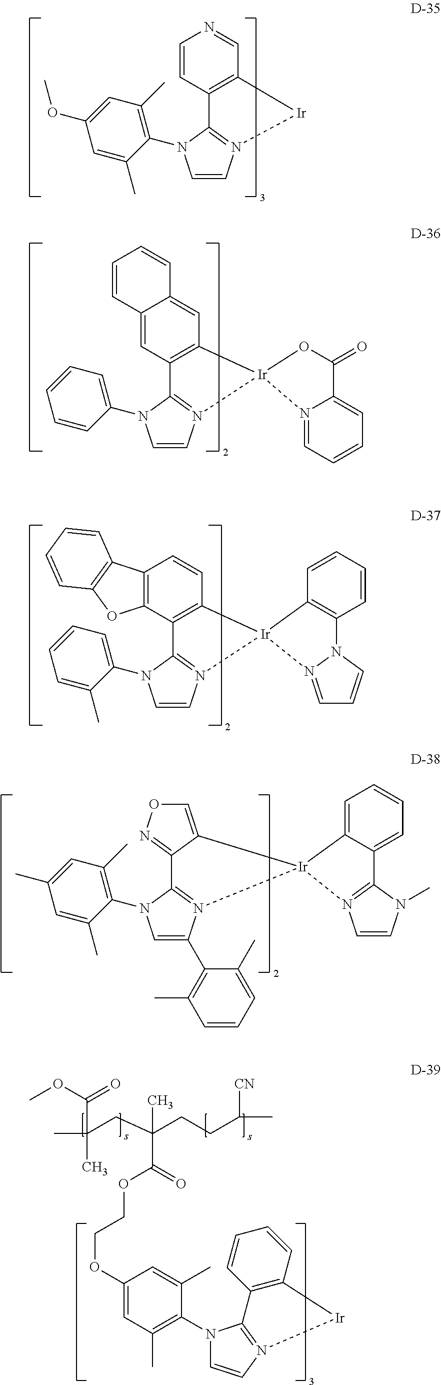

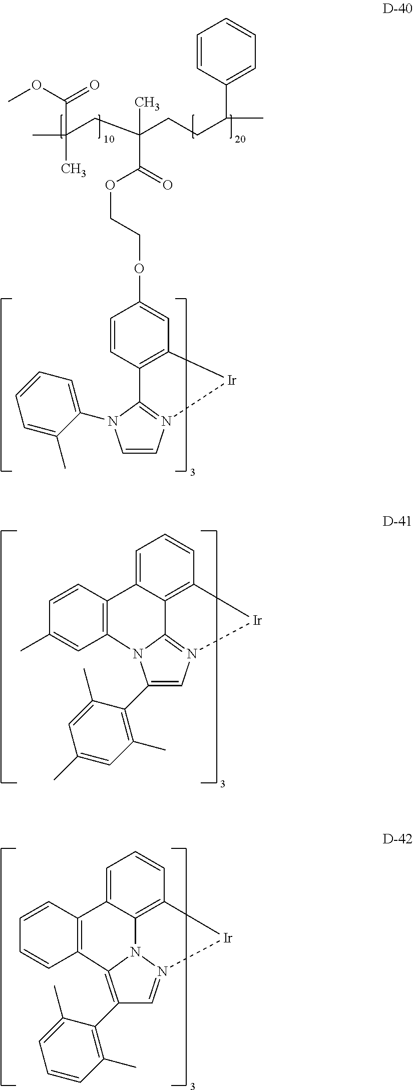

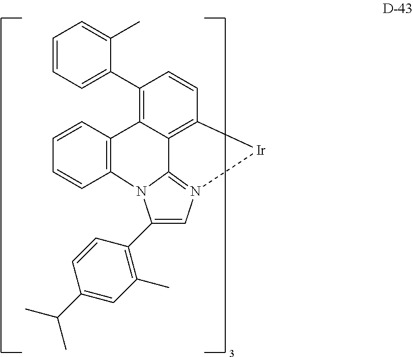

These metal complexes can be synthesized by applying a method described in such as Organic Letter, vol. 3, No. 16, pp. 2579-2581 (2001), Inorganic Chemistry vol. 30, No. 8, pp. 1685-1687 (1991), J. Am. Chem. Soc., vol. 123, p. 4304 (2001), Inorganic Chemistry vol. 40, No. 7, pp. 1704-1711 (2001), Inorganic Chemistry vol. 41, No. 12, pp. 3055-3066 (2002), New Journal of Chemistry, vol. 26, p. 1171 (2002), Organic Letters Vol. 18, No. 3, pp. 415-418 (2006), and reference documents described in these documents.

### <Constituting Layers of Organic EL Element>

Each of the layers which constitute the organic EL element of the present invention will now be sequentially detailed. Preferred embodiments of the organic EL element of the present invention will be described below, however, the present invention is not limited to these.

(i) anode/light emitting layer/electron transport layer/cathode
(ii) anode/positive hole transport layer/light emitting layer/electron transport layer/cathode
(iii) anode/positive hole transport layer/light emitting layer/positive hole inhibition layer/electron transport layer/cathode
(iv) anode/positive hole transport layer/light emitting layer/positive hole inhibition layer/electron transport layer/cathode buffer layer/cathode
(v) anode/anode buffer layer/positive hole transport layer/light emitting layer/positive hole inhibition layer/electron transport layer/cathode buffer layer/cathode

With respect to the organic EL element of the present invention, the maximum emitting wavelength of the blue light emitting layer is preferably from 430 nm to 480 nm, the maximum emitting wavelength of the green light emitting layer is preferably from 510 nm to 550 nm and the maximum emitting wavelength of the red light emitting layer is preferably from 600 nm to 640 nm.

At least three kinds light emitting layers may be laminated to form a white light emitting layer.

Further, there may be present a non-light emitting intermediate layer between the light emitting layers. The organic EL element of the present invention have preferably a white light emitting layer, and lighting devices employing these are preferred.

Each of the layers which constitute the organic EL elements of the present invention will now be sequentially detailed.

### <Light Emitting Layer>

The light emitting layer of the present invention is a layer, which emits light via recombination of electrons and positive holes injected from an electrode or a layer such as an electron transport layer or a positive hole transport layer. The light emission portion may be present either within the light emitting layer or at the interface between the light emitting layer and an adjacent layer thereof.

The total thickness of the light emitting layer is not particularly limited. However, in view of the layer homogeneity, the minimization of application of unnecessary high voltage during light emission, and the stability enhancement of the emitted light color against the drive electric current, the layer thickness is regulated preferably in the range of 2 nm to 5 μm, more preferably in the range of 2 nm to 200 nm, but most preferably in the range of 10 nm to 20 nm.

The light emitting layer can be prepared by forming a thin layer made of a polymer containing a partial structure represented by Formula (1) and a light emitting dopant with a thin layer forming method such as a vacuum evaporation method, a spin coating method, a cast method, a LB method, or an ink-jet method.

The light emitting layer of the organic EL element of the present invention incorporates a light emitting dopant (a phosphorescent emitting dopant (a phosphorescence dopant or a fluorescent dopant) and a light emitting host compound.

### (Light Emitting Dopant Compound)

The light emitting dopant compound will now be described.

As light emitting dopants according to the present invention, it can be employed fluorescent dopants (also referred to as fluorescent compounds) and phosphorescent dopants (also referred to as phosphorescent emitting materials, phosphorescent compounds or phosphorescence emitting compounds). From the viewpoint of obtaining an organic EL element exhibiting high light emitting efficiency, a compound represented by the foregoing Formula (D-1) is contained in the light emitting layer of the organic EL element of the present invention as a light emitting dopant which acts as a phosphorescence emitting dopant.

### (Phosphorescent Dopant)

A phosphorescence dopant of the present invention will be described.

The phosphorescent dopant of the present invention is a compound, wherein emission from an excited triplet state thereof is observed, specifically, emitting phosphorescence at room temperature (25° C.) and exhibiting a phosphorescence quantum yield of at least 0.01 at 25° C. The phosphorescence quantum yield is preferably at least 0.1.

The phosphorescence quantum yield can be determined via a method described in page 398 of Bunko II of Dai 4 Han Jikken Kagaku Koza 7 (Spectroscopy II of 4th Edition Lecture of Experimental Chemistry 7) (1992, published by Maruzen Co., Ltd.). The phosphorescence quantum yield in a solution can be determined using appropriate solvents. However, it is only necessary for the phosphorescent dopant of the present invention to exhibit the above phosphorescence quantum yield using any of the appropriate solvents.

Two kinds of principles regarding emission of a phosphorescent dopant are cited. One is an energy transfer-type, wherein carriers recombine on a host compound on which the carriers are transferred to produce an excited state of the host compound, and then via transfer of this energy to a phosphorescent dopant, emission from the phosphorescence-emitting dopant is realized. The other is a carrier trap-type, wherein a phosphorescence-emitting dopant serves as a carrier trap and then carriers recombine on the phosphorescent dopant to generate emission from the phosphorescent dopant. In each case, the excited state energy of the phosphorescent dopant is required to be lower than that of the host compound.

In the present invention, the phosphorescence emitting dopant can be suitably chosen from the compounds represented by the above-mentioned Formula (D-1), and it can be used.

Moreover, in the present invention, the well-known phosphorescence emitting dopants used in the light emitting layer of an organic EL device can be used besides the compounds chosen from the compound represented by above-mentioned Formula (D-1).

It is preferable that the light emitting layer of the organic EL element of the present invention contains two or more sorts of phosphorescence emitting dopants. Moreover, as dope concentration of the dopant in the light emitting layer, it is preferable to adjust the dope concentration in the range 10 mass % to 40 mass %, and more preferably, to adjust in the range 15 mass % to 30 mass %.

Examples of a well-known compound used as a phosphorescence emitting dopant are shown below. However, the present invention is not limited to these. These compounds can be synthesized with the method described in Inorg. Chem. Volume 40, 1704-1711, for example.

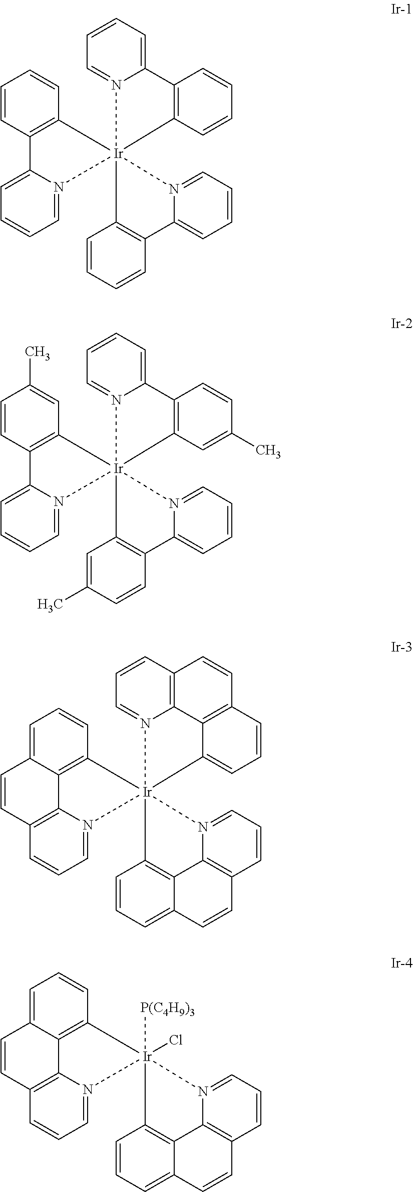

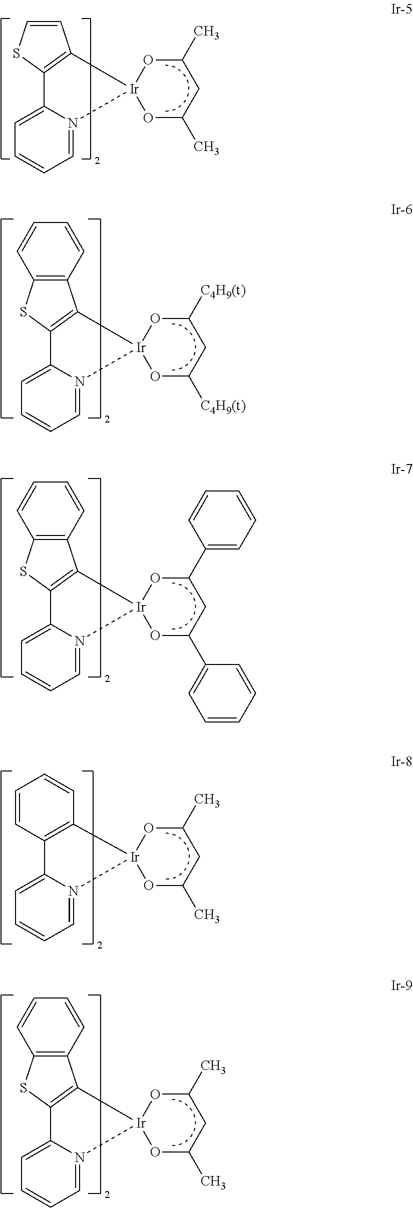

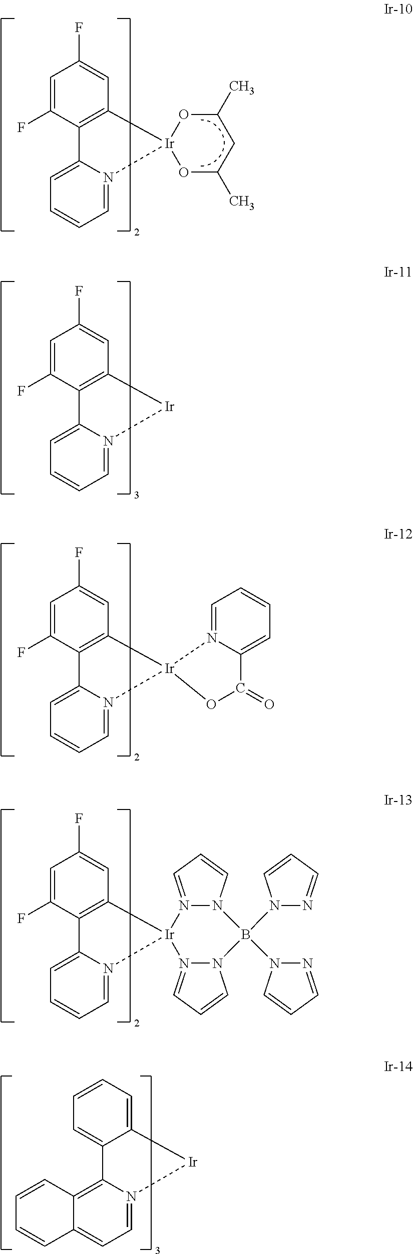

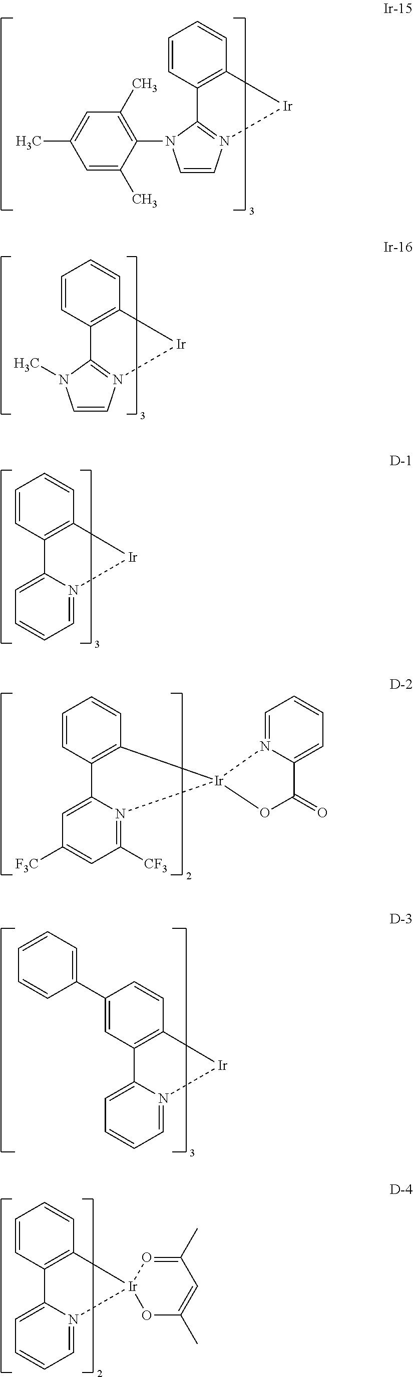

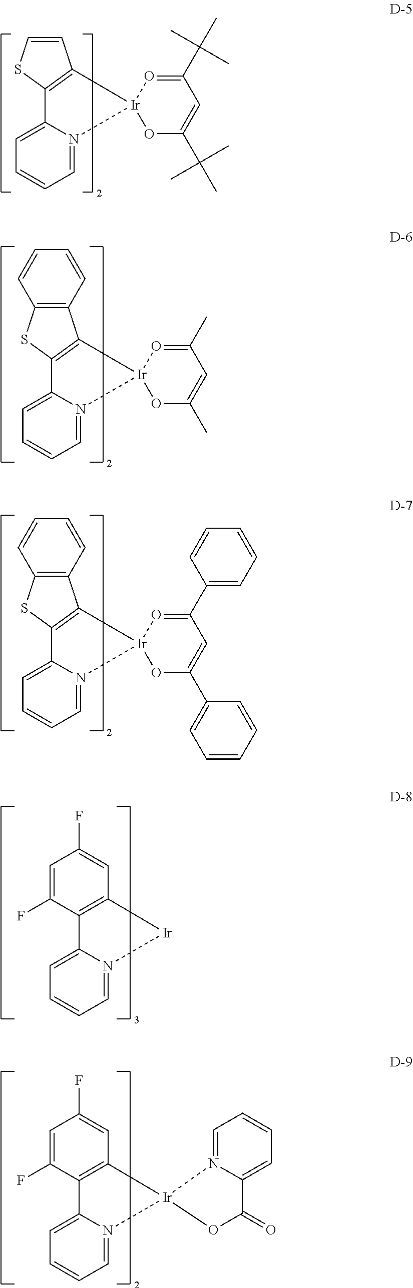

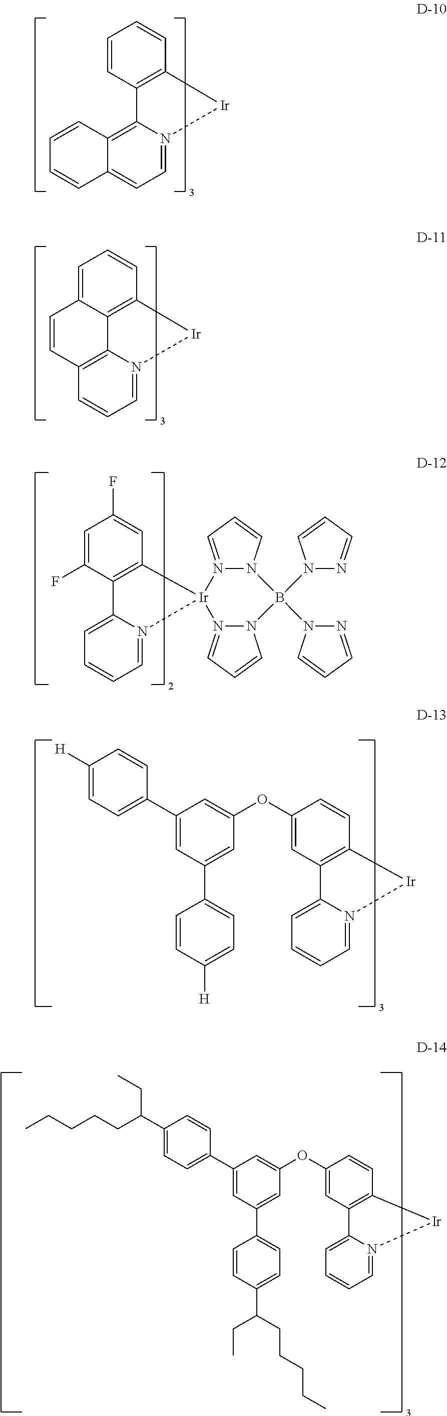

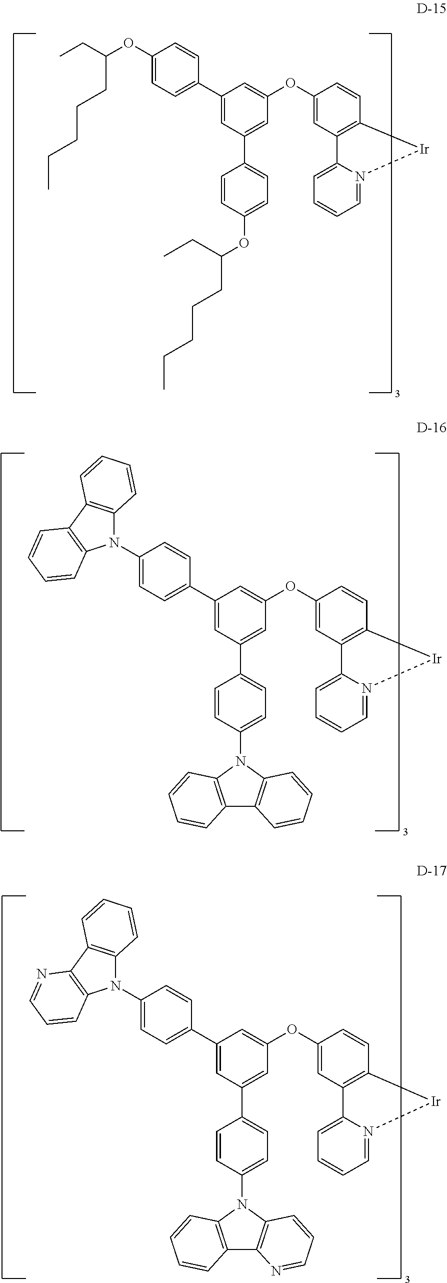

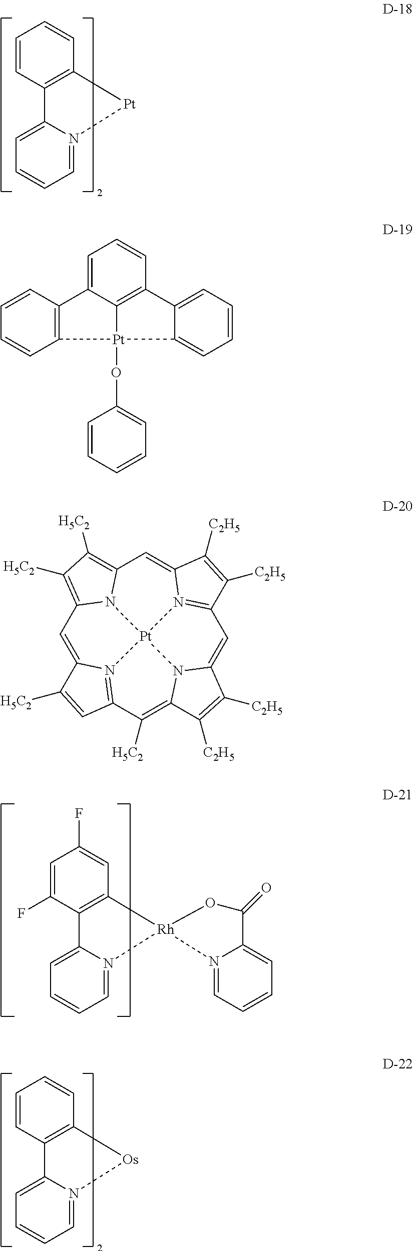

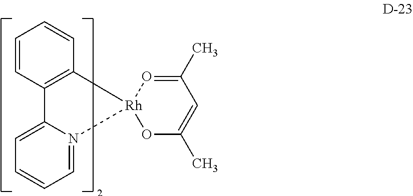

### (Light Emitting Host Compounds (Also Referred to as Light Emitting Hosts)

“Host compounds”, as described in the present invention, are defined as compounds, incorporated in a light emitting layer, which result in a mass ratio of at least 20% in the above layer and also result in a phosphorescent quantum yield of the phosphorescence emission of less than 0.1. Further, of compounds incorporated in the light emitting layer, it is preferable that the mass ratio in the aforesaid layer is at least 20%.

Structures of the light emitting host employed in the present invention are not particularly limited. The conventionally known host compounds in organic EL elements can be used. Representative compounds include those having a basic skeleton such as carbazole derivatives, triarylamine derivatives, aromatic compound derivatives, nitrogen-containing heterocyclic compounds, thiophene derivatives, furan derivatives, oligoarylene compounds, carboline derivatives, or multi-azacarbazole derivatives (here, “a multi-azacarbazole derivative” indicates a ring structure in which at least one of the carbon atoms constituting the carboline ring is replaced with a nitrogen atom).

A known light emitting host (or emission host) which may be used in the present invention is preferably a compound having a positive hole transporting ability and an electron transporting ability, as well as preventing elongation of an emission wavelength and having a high Tg (a glass transition temperature).

It may be used an emission host compound of the present invention singly or it may be used in combination with plural host compounds, which may be other host compound of the present invention or a known host compound.

It is possible to control the transfer of charges by making use of a plurality of host compounds, which results in high efficiency of an organic EL element.

In addition, it is possible to mix a different emission lights by making use of a plurality of known phosphorescent dopants as described above. Any required emission color can be obtained thereby.

Further, an emission host used in the present invention may be either a low molecular weight compound or a polymer compound having a repeating unit, in addition to a low molecular weight compound provided with a polymerizing group such as a vinyl group and an epoxy group (an evaporation polymerizing emission host). These compounds may be used singly or in combination of two or more compounds.

As specific examples of an emission host compounds, the compounds described in the following Documents are preferable.

For example, JP-A Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837.

Next, an injection layer, an inhibition layer and an electron transport layer, which are used as a constituting layer of an organic EL element concerning to the present invention, will be described.

### <Injection Layer: Electron Injection Layer, Positive Hole Injection Layer>

An injection layer is appropriately provided and includes an electron injection layer and a positive hole injection layer, which may be arranged between an anode and an emitting layer or a positive transfer layer, and between a cathode and an emitting layer or an electron transport layer, as described above.

An injection layer is a layer which is arranged between an electrode and an organic layer to decrease an operating voltage and to improve an emission luminance, which is detailed in volume 2, chapter 2 (pp. 123-166) of “Organic EL Elements and Industrialization Front thereof (Nov. 30, 1998, published by N. T. S Corp.)”, and includes a positive hole injection layer (an anode buffer layer) and an electron injection layer (a cathode buffer layer).

An anode buffer layer (a positive hole injection layer) is also detailed in such as JP-A Nos. 9-45479, 9-260062 and 8-288069, and specific examples include such as a phthalocyanine buffer layer comprising such as copper phthalocyanine, an oxide buffer layer comprising such as vanadium oxide, an amorphous carbon buffer layer, and a polymer buffer layer employing conductive polymer such as polyaniline (or called as emeraldine) or polythiophene.

A cathode buffer layer (an electron injection layer) is also detailed in such as JP-A Nos. 6-325871, 9-17574 and 10-74586, and specific examples include a metal buffer layer represented by strontium and aluminum, an alkali metal compound buffer layer represented by lithium fluoride, an alkali earth metal compound buffer layer represented by magnesium fluoride, and an oxide buffer layer represented by aluminum oxide.

An electron injection material conventionally used is LiF. However, from the viewpoint of decreasing the driving voltage of the element, KF and CsF are preferably used.

The above-described buffer layer (injection layer) is preferably a very thin layer, and the layer thickness is preferably in a range of 0.1 nm-5 μm although it depends on a raw material.

### <Inhibition Layer: Positive Hole Inhibition Layer, Electron Inhibition Layer>

An inhibition layer is appropriately provided in addition to the basic constitution layers composed of organic thin layers as described above. Examples are described in such as JP-A Nos. 11-204258 and 11-204359 and p. 273 of “Organic EL Elements and Industrialization Front Thereof (Nov. 30 (1998), published by N. T. S Corp.)” is applicable to a positive hole inhibition (hole block) layer according to the present invention.

A positive hole inhibition layer, in a broad meaning is provided with a function of electron transport layer, being comprised of a material having a function of transporting an electron but a very small ability of transporting a positive hole, and can improve the recombination probability of an electron and a positive hole by inhibiting a positive hole while transporting an electron.

Further, a constitution of an electron transport layer described above can be appropriately utilized as a positive hole inhibition layer according to the present invention.

The positive hole inhibition layer of the organic EL element of the present invention is preferably arranged adjacent to the light emitting layer.

It is preferable that the positive hole inhibition layer incorporates a carbazole derivative, or a carboline derivative, or a diazacarbazole derivative listed as a host compound as described above.

Further, in the present intention, in the case in which a plurality of light emitting layers which differ in a plurality of different emitted light colors, it is preferable that the light emitting layer which results in the shortest wavelength of the emitted light maximum wavelength is nearest to the anode in all light emitting layers. However, in such a case, it is preferable to additionally arrange the positive hole inhibition layer between the aforesaid shortest wavelength layer and the light emitting layer secondly near the anode.

Further, at least 50% by mass of the compounds incorporated in the positive hole inhibition layer arranged in the aforesaid position preferably exhibits the ionization potential which is greater by at least 0.3 eV than that of the host compounds of the aforesaid shortest wavelength light emitting layer.

On the other hand, the electron inhibition layer, as described herein, has a function of the positive hole transport layer in a broad sense, and is composed of materials having markedly small capability of electron transport, while having capability of transporting positive holes and enables to enhance the recombination probability of electrons and positive holes by inhibiting electrons, while transporting electrons.

Further, it is possible to employ the constitution of the positive hole transport layer, described below, as an electron inhibition layer when needed. The thickness of the positive hole inhibition layer and the electron transport layer according to the present invention is preferably in the range of 3 nm to 100 nm, but more preferably it is in the range of 5 nm to 30 nm.

### <Positive Hole Transport Layer>

A positive hole transport layer contains a material having a function of transporting a positive hole, and in a broad meaning, a positive hole injection layer and an electron inhibition layer are also included in a positive hole transport layer. A single layer of or plural layers of a positive hole transport layer may be provided.

A positive hole transport material is those having any one of a property to inject or transport a positive hole or a barrier property to an electron, and may be either an organic substance or an inorganic substance. In the present invention, a polymer containing a partial structure represented by the foregoing Formula (1) is used, and the following known compounds may be used therewith.

For example, listed are a triazole derivative, an oxadiazole derivative, an imidazole derivative, a polyarylalkane derivative, a pyrazolone derivative, a phenylenediamine derivative, an arylamine derivative, an amino substituted chalcone derivative, an oxazole derivatives, a styrylanthracene derivative, a fluorenone derivative, a hydrazone derivative, a stilbene derivative, a silazane derivative, an aniline type copolymer, or conductive polymer oligomer and specifically preferably such as thiophene oligomer.

As a positive hole transport material, those described above can be utilized, however, it is preferable to utilized a porphyrin compound, an aromatic tertiary amine compound and a styrylamine compound, and specifically preferably an aromatic tertiary amine compound.

This positive hole transport layer can be prepared by forming a thin layer made of the above-described positive hole transport material according to a method well known in the art such as a vacuum evaporation method, a spin coating method, a cast method, an inkjet method and a LB method.

The layer thickness of a positive hole transport layer is not specifically limited, however, it is generally 5 nm to 5 μm, and preferably it is 5 nm to 200 nm. This positive transport layer may have a single layer structure comprised of one or not less than two types of the above described materials.

Further, it is possible to employ a positive hole transport layer of a higher p property which is doped with impurities. As its example, listed are those described in each of JP-A Nos. 4-297076, 2000-196140, 2001-102175, as well as in J. Appl. Phys., 95, 5773 (2004).

### <Electron Transport Layer>

An electron transport layer is composed of a material having a function to transfer an electron, and an electron injection layer and a positive hole inhibition layer are included in an electron transport layer in a broad meaning. A single layer or plural layers of an electron transport layer may be provided.

Electron transport materials employed in a single electron transport layer, or in an adjacent layer to the cathode side when a plurality of electron transport layers are incorporated, they are only required to have a function of transporting electrons ejected from the cathode to the light emitting layer. As such materials, any of the conventional compounds may be selected and employed. Examples of them include: a nitro-substituted fluorene derivative, a diphenylquinone derivative, a thiopyradineoxide derivative, carbodiimide, a fluorenylidenemethane derivative, anthraquinonedimethane, an anthrone derivative, and an oxadiazole derivative.

Further, as examples of an oxadiazole derivative described above, the following compounds can be used as an electron transport material: a thiazole derivative in which an oxygen atom in the oxadiazole ring is replaced with a sulfur atom; a quinoxaline derivative which contains a quinoxaline ring known as an electron withdrawing group; a carboline derivative (a compound in which one of carbon atoms constituting a carbazole ring is replaced with a nitrogen atom); a multi-azacarbazole derivative (a compound in which at least one of the carbon atoms constituting the carboline ring is replaced with a nitrogen atom); and pyridine derivative.

Specifically, it is preferable to use a multi-aza carbazole derivative having a pyridine ring or a number of N of 2 to 5, from the viewpoint of driving voltage of an organic EL element.

Polymer materials, in which these materials are introduced in a polymer chain or these materials form the main chain of polymer, can be also utilized.

Further, a metal complex of a 8-quinolinol derivative such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, can be also utilized as an electron transport material.

Further, metal-free or metal phthalocyanine, or a phthalocyanine derivative whose terminal is substituted by an alkyl group and a sulfonic acid group, can be preferably utilized as an electron transport material. In addition, a distyrylpyradine derivative which was cited as a light emitting material can be used as an electron transport material. Moreover, similarly to the case of a positive hole injection layer and to the case of a positive hole transfer layer, an inorganic semiconductor such as an n-type-Si and an n-type-SiC can be also utilized as an electron transport material.

The electron transport layer can be prepared by forming a thin layer made of the above-described electron transport material with a known method such as: a vacuum evaporation method, a spin coating method, a cast method, a printing method including an ink-jet method, or a LB method.

The layer thickness of the electron transport layer of the present invention is preferably adjusted in the range of 5 nm to 5 μm, and preferably in the range of 5 nm to 200 nm.

This electron transport layer may be a single layer structure containing of one or more types of the above described materials.

Further, it is possible to employ an electron transport layer doped with impurities, which exhibits high n property. Examples thereof include those, described in JP-A Nos. 4-297076, 10-270172, 2000-196140, 2001-102175, as well as J. Appl. Phys., 95, 5773 (2004).

In the present invention, it is preferable to use an electron transport layer exhibiting a high n-property to prepare an EL element of small electric power consumption.

Next, there will be listed specific example compounds used for positive hole transport materials, light emitting hosts, and electron transport materials of the organic EL element of the present invention. However, the present invention is not limited to them.

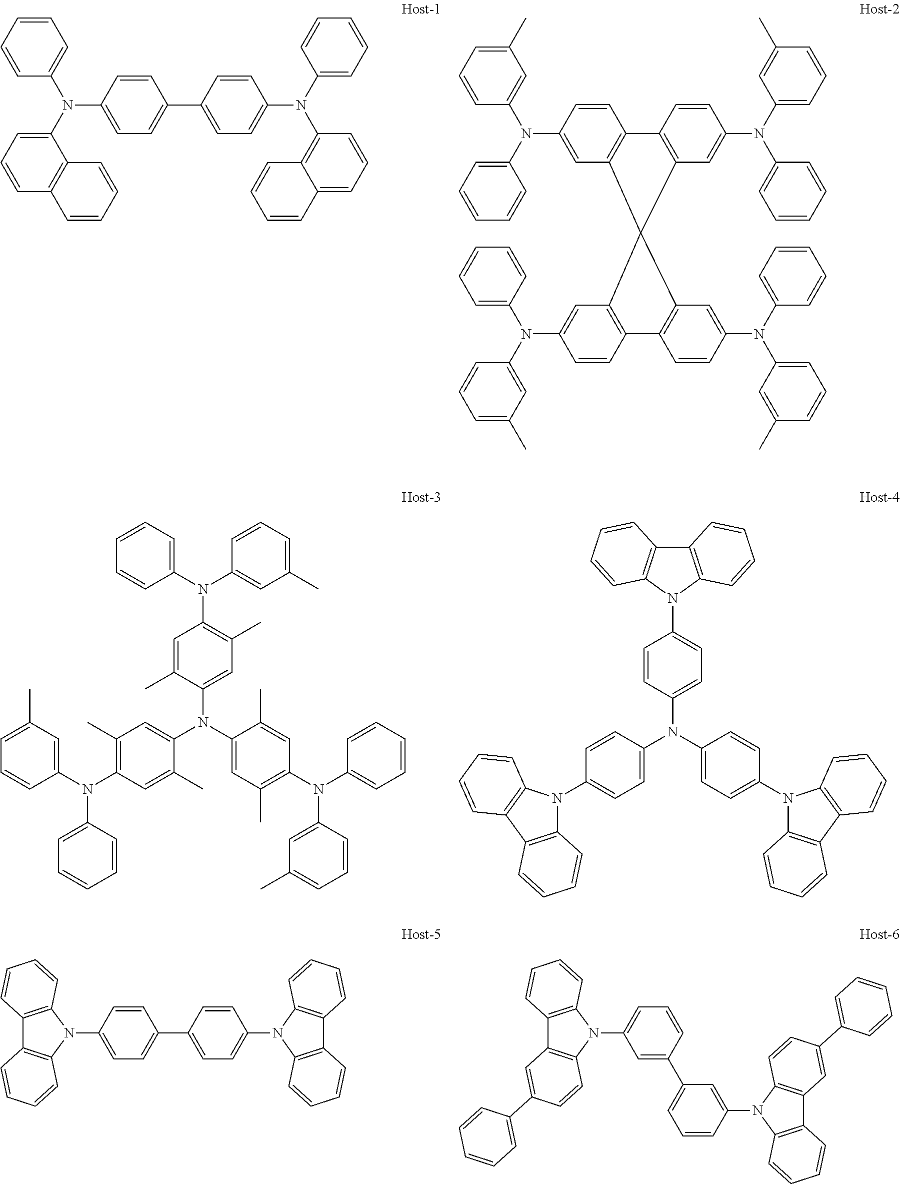

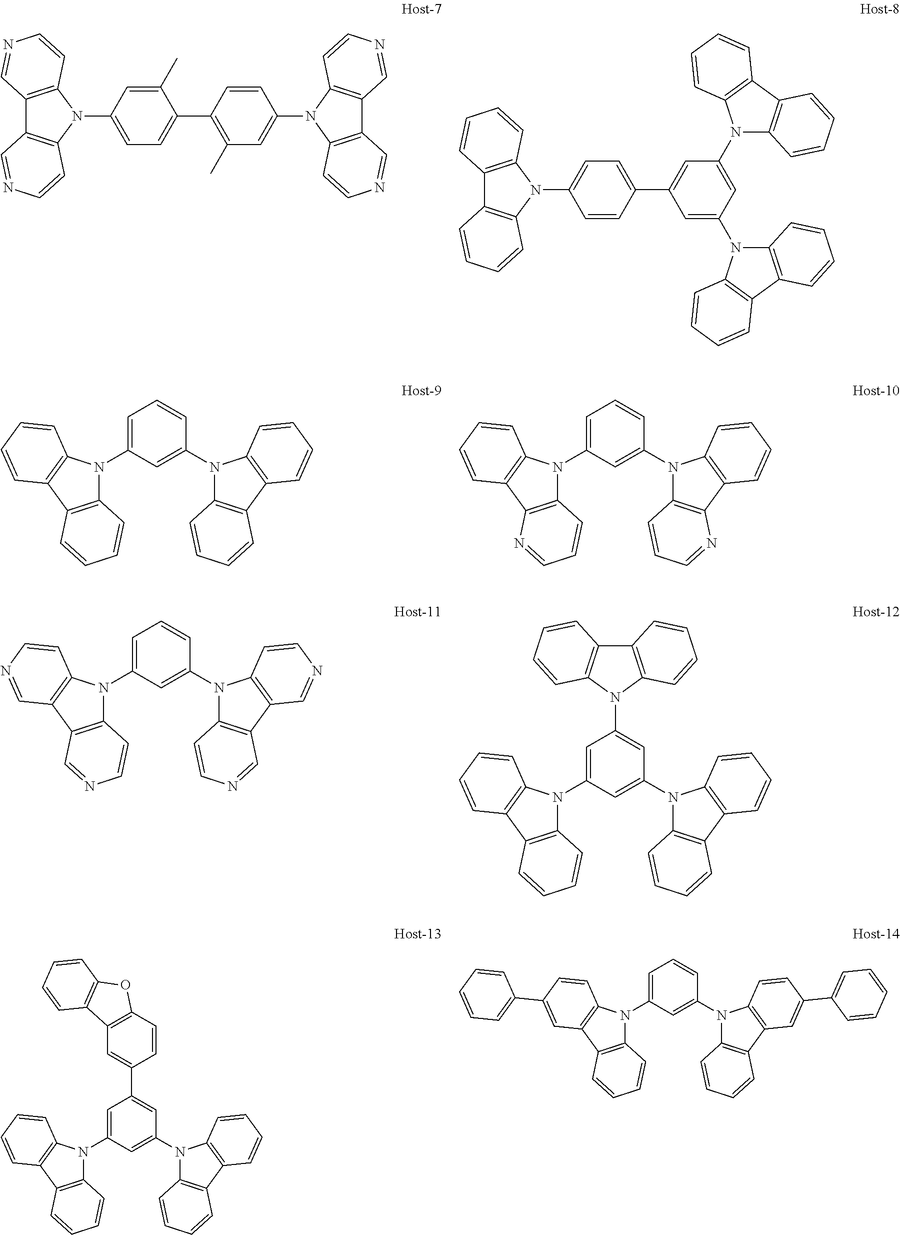

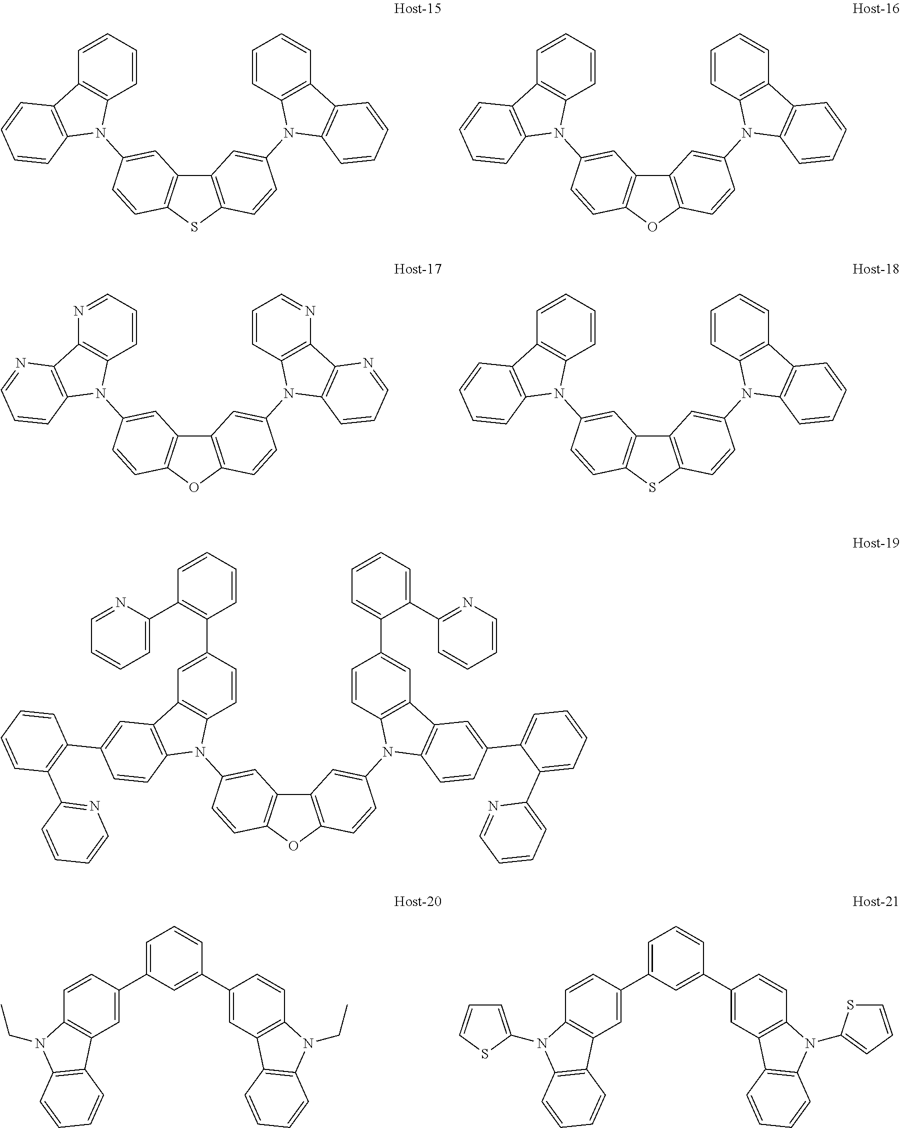

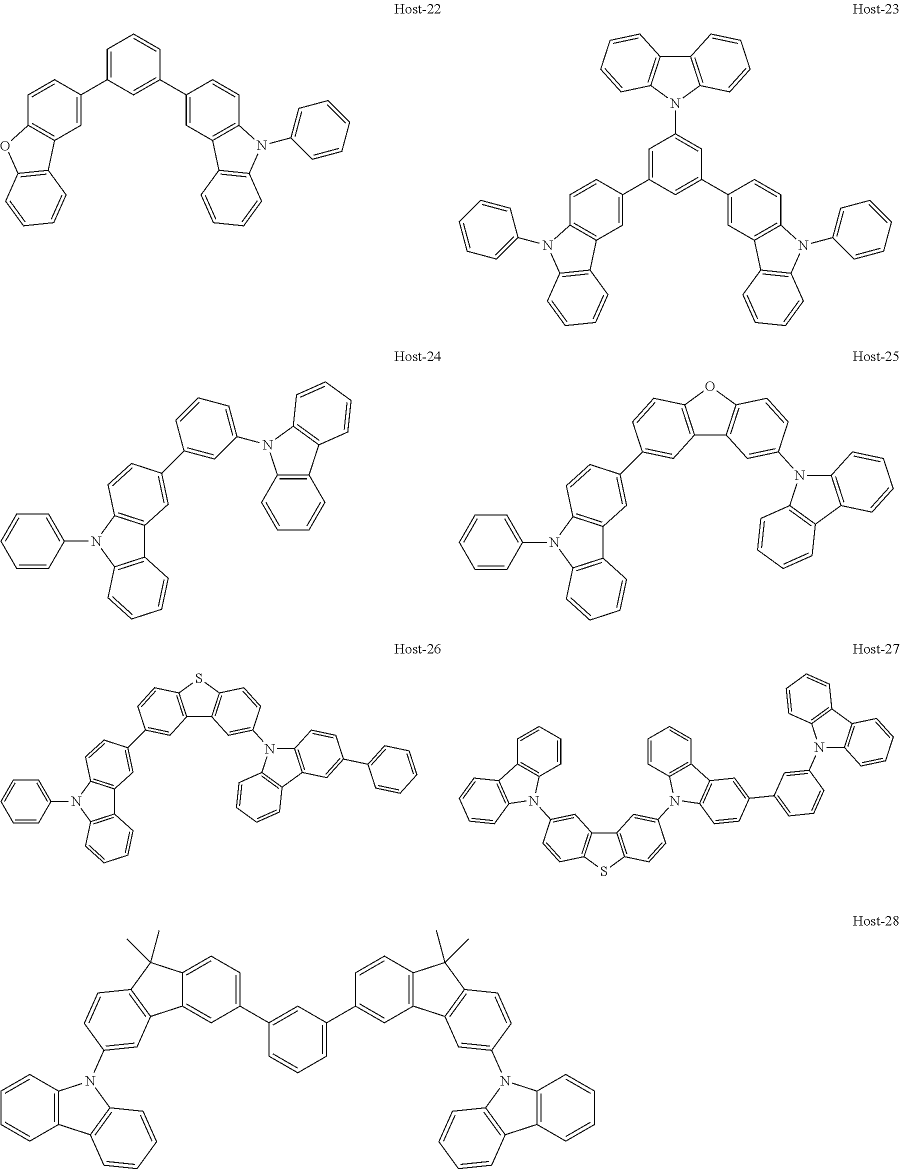

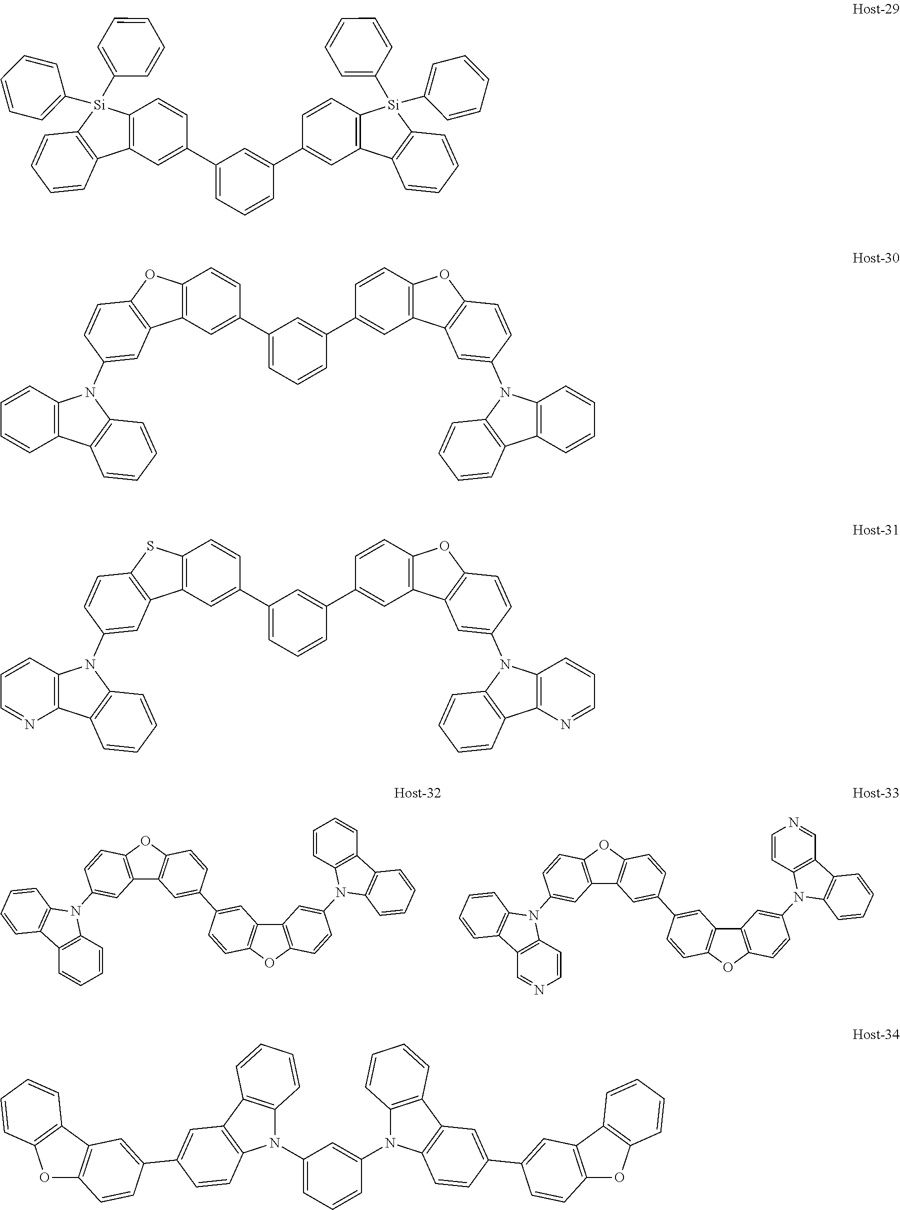

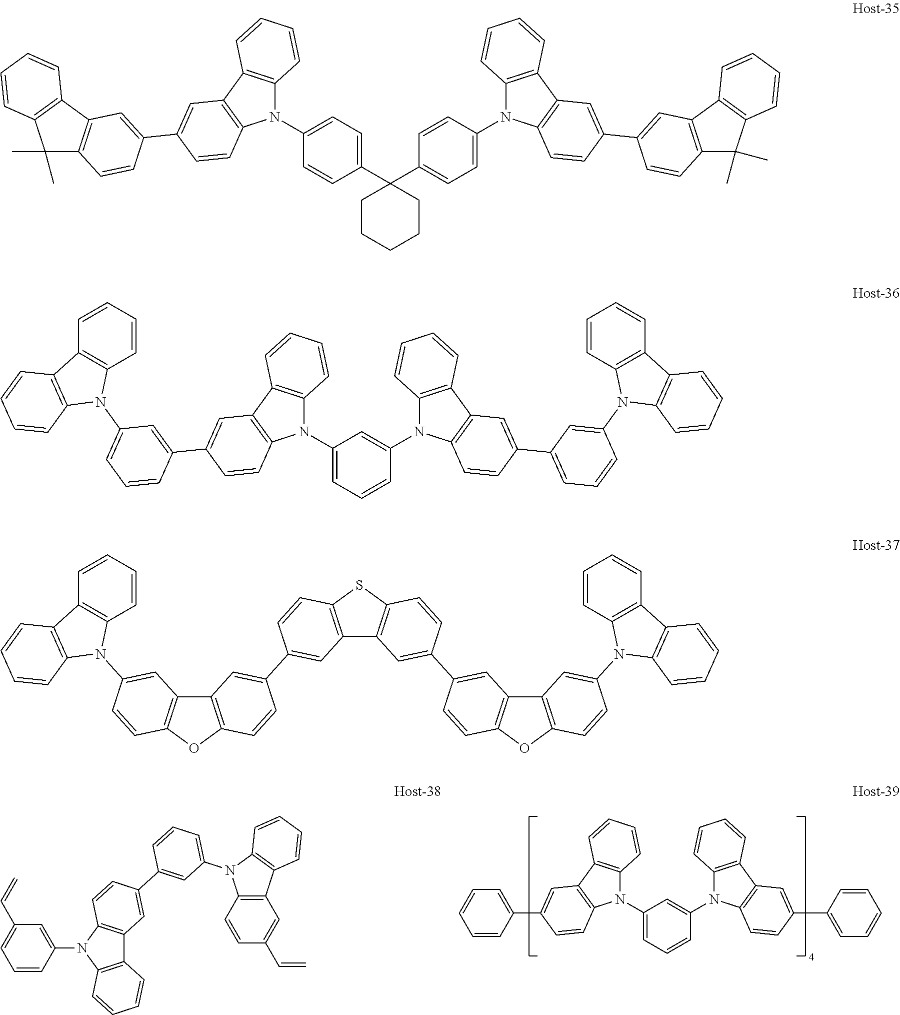

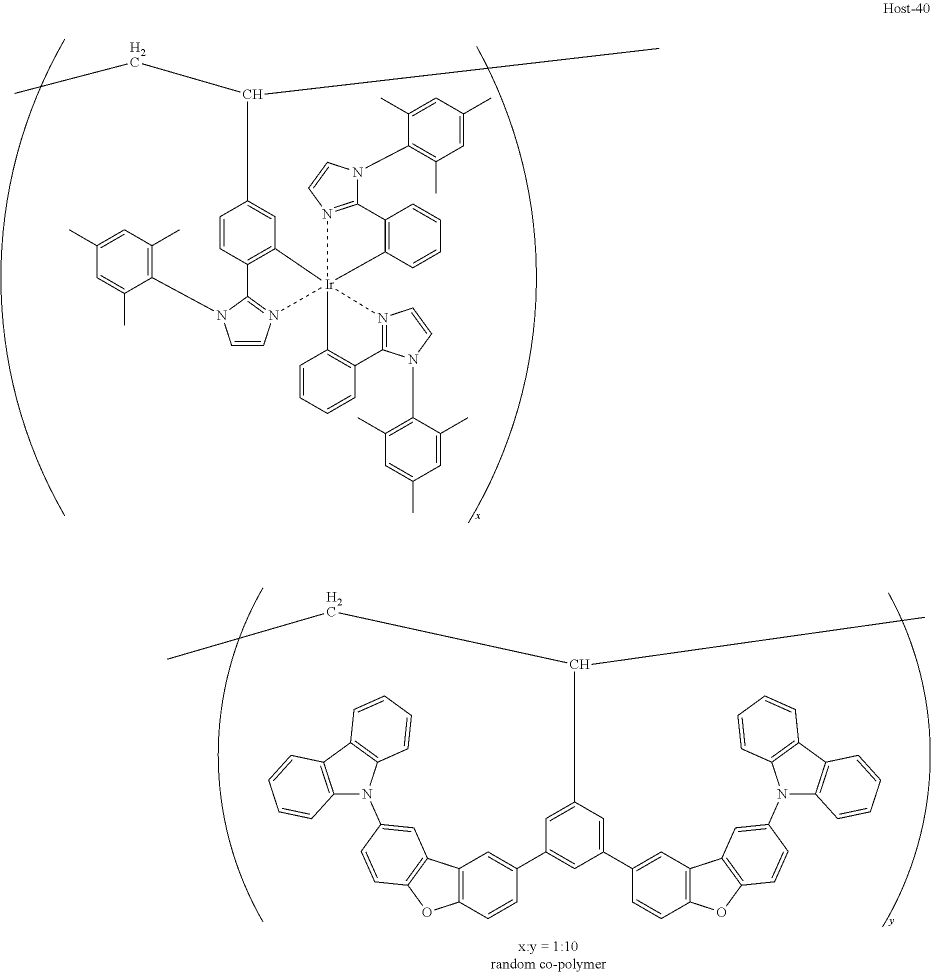

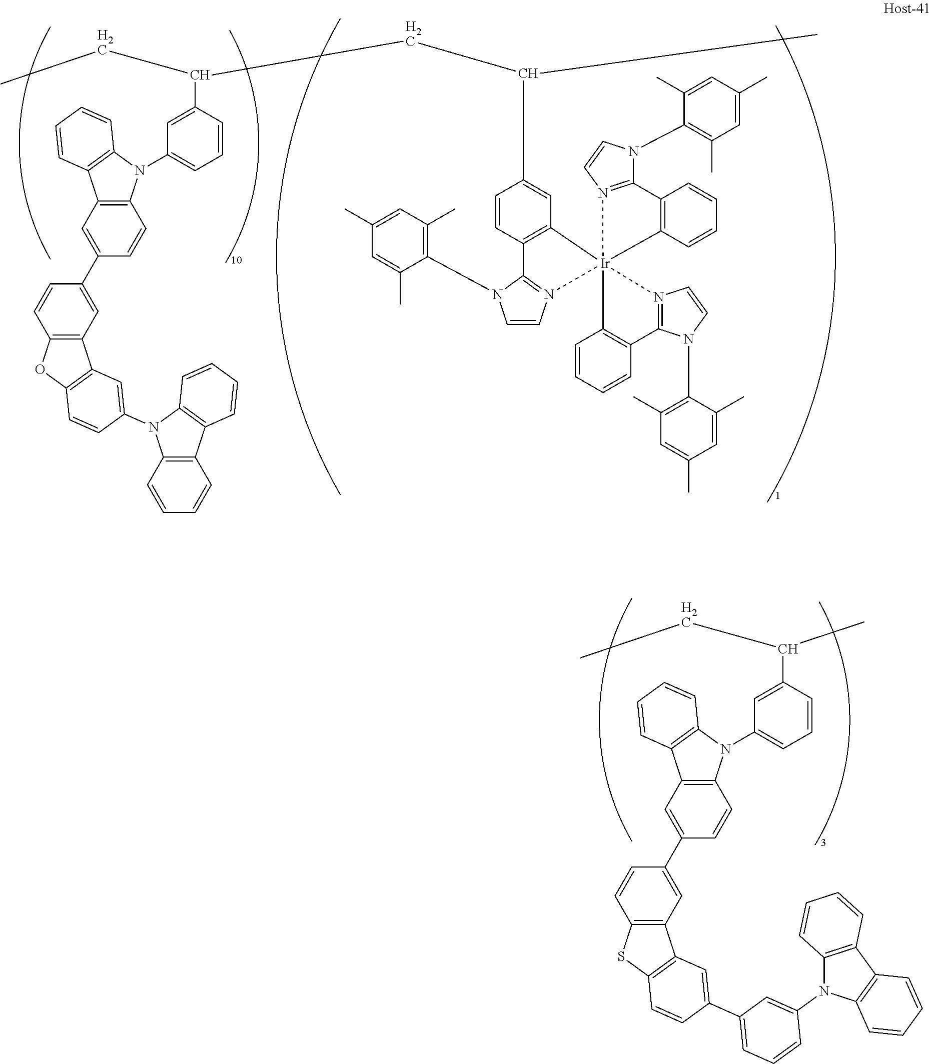

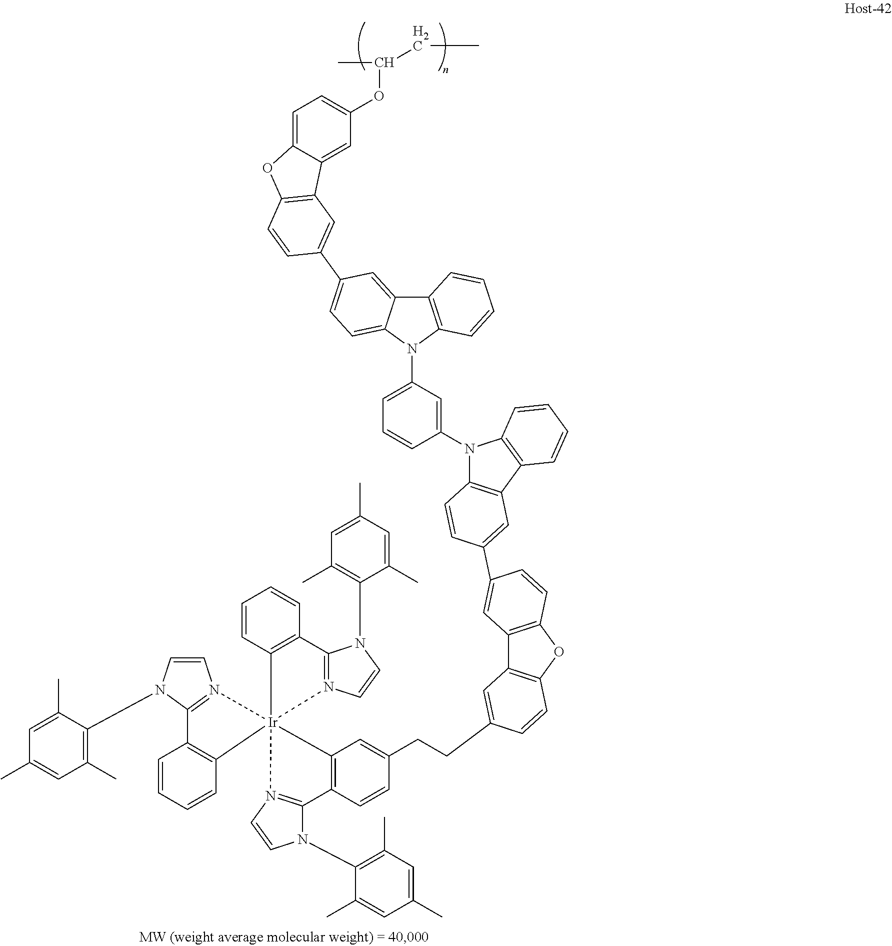

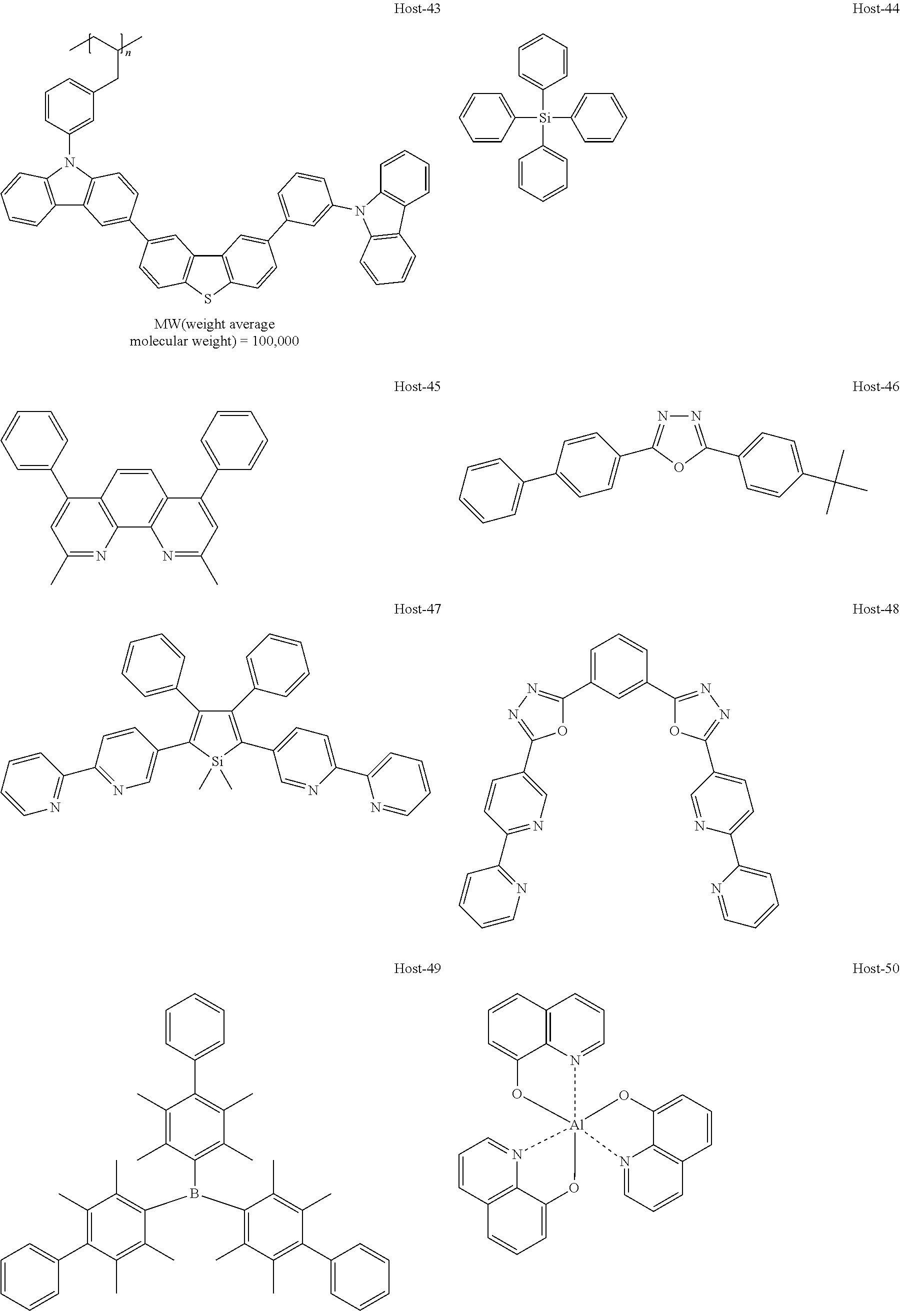

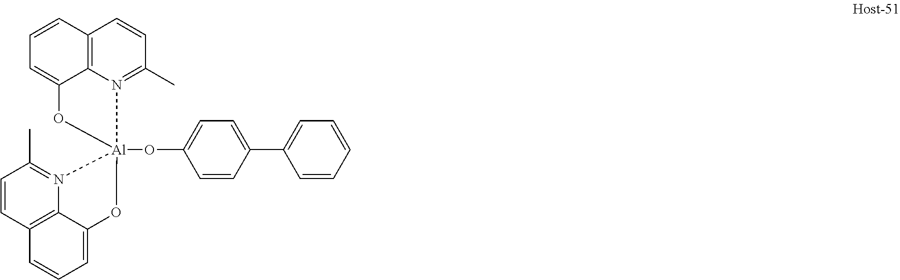

### <Anode>

As an anode according to an organic EL element of the present invention, those comprising metal, alloy, a conductive compound, which is provided with a large work function (not less than 4 eV), and a mixture thereof as an electrode substance are preferably utilized. Specific examples of such an electrode substance include a conductive transparent material such as metal like Au, Cut indium tin oxide (ITO), SnO₂ and ZnO. Further, a material such as IDIXO (In₂O₃—ZnO), which can prepare an amorphous and transparent electrode, may be also utilized. As for an anode, these electrode substances may be made into a thin layer by a method such as evaporation or spattering and a pattern of a desired form may be formed by means of photolithography, or in the case of requirement of pattern precision is not so severe (not less than 100 μm), a pattern may be formed through a mask of a desired form at the time of evaporation or spattering of the above-described substance. Alternatively, when coatable materials such as organic electrically conductive compounds are employed, it is possible to employ a wet system filming method such as a printing system or a coating system. When emission is taken out of this anode, the transmittance is preferably set to not less than 10% and the sheet resistance as an anode is preferably not more than a few hundreds Ω/□.

Further, although the layer thickness depends on a material, it is generally selected in a range of 10 nm to 1,000 nm and preferably of 10 nm to 200 nm.

### <Cathode>

On the other hand, as a cathode according to the present invention, metal, alloy, a conductive compound and a mixture thereof, which have a small work function (not more than 4 eV), are utilized as an electrode substance.

Specific examples of such an electrode substance includes such as sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture and rare earth metal.

Among them, with respect to an electron injection property and durability against such as oxidation, preferable are a mixture of electron injecting metal with the second metal which is stable metal having a work function larger than electron injecting metal, such as a magnesium/silver mixture, a magnesium/aluminum mixture, a magnesium/indium mixture, an aluminum/aluminum oxide (Al₂O₃) mixture and a lithium/aluminum mixture, and aluminum.

A cathode can be prepared by forming a thin layer of these electrode substances with a method such as evaporation or sputtering.

Further, the sheet resistance as a cathode is preferably not more than a few hundreds Ω/□ and the layer thickness is generally selected in the range of 10 nm to 5 μm and preferably of 50 nm to 200 nm.

In order to make transmit emitted light, either one of an anode or a cathode of an organic EL element is preferably transparent or translucent to improve the emission luminance.

Further, after forming, on the cathode, the above metals at a film thickness of 1 nm to 20 nm, it is possible to prepare a transparent or translucent cathode in such a manner that electrically conductive transparent materials are prepared thereon. By applying the above, it is possible to produce an element in which both anode and cathode are transparent.

### <Substrate>

A substrate according to an organic EL element of the present invention is not specifically limited with respect to types of such as glass and plastics. They me be transparent or opaque.

A transparent substrate is preferable when the emitting light is taken from the side of substrate. Substrates preferably utilized includes such as glass, quartz and transparent resin film.

A specifically preferable substrate is a resin film capable of providing an organic EL element with a flexible property.

Examples of a resin film includes: polyesters such as polyethylene terephthalate (PET) and polyethylene naphthalate (PEN); polyethylene, polypropyrene; cellulose esters or their derivatives such as cellophane, cellulose diacetate, cellulose triacetate, cellulose acetate butylate, cellulose acetate propionate (CAP), cellulose acetate phthalate (TAC) and cellulose nitrate; polyvinylidene chloride, polyvinyl alcohol, polyethylene vinyl alcohol, syndiotactic polystyrene, polycarbonate, norbornene resin, polymethylpentene, polyether ketone, polyimide, polyether sulfone (PES), polyphenylene sulfide, polysulfones, polyetherimide, polyether ketone imide, polyamide, fluororesin, Nylon, polymethylmethacrylate, acrylic resin, polyacrylate; and cycloolefine resins such as ARTON (produced by JSR Co. Ltd.) and APEL (produce by Mitsui Chemicals, Inc.)

On the surface of a resin film, it may be formed a film incorporating an inorganic or an organic compound or a hybrid film incorporating both compounds. It is preferable to be a barrier film having a water vapor permeability of at most 0.01 g/(m²·24 h) (25±0.5° C., and relative humidity (90±2) % RH) determined based on JIS K 7129-1992. Further, it is preferable to be a high barrier film having an oxygen permeability of at most 1×10⁻³ cm³/(m²·24 h·MPa) determined based on JIS K 7126-1987, and having a water vapor permeability of at most 10⁻³ g/(m²·24 h). It is more preferable that the aforesaid water vapor permeability is not more than 10⁻⁵ g/(m²·24 h).

As materials forming a barrier film, employed may be those which retard penetration of moisture and oxygen, which deteriorate the element. For example, it is possible to employ silicon oxide, silicon dioxide, and silicon nitride. Further, in order to improve the brittleness of the aforesaid film, it is more preferable to achieve a laminated layer structure of inorganic layers and organic layers. The laminating order of the inorganic layer and the organic layer is not particularly limited, but it is preferable that both are alternatively laminated a plurality of times.

Barrier film forming methods are not particularly limited, and examples of employable methods include a vacuum deposition method, a sputtering method, a reactive sputtering method, a molecular beam epitaxy method, a cluster ion beam method, an ion plating method, a plasma polymerization method, a plasma CVD method, a laser CVD method, a thermal CVD method, and a coating method. Of these, specifically preferred is a method employing an atmospheric pressure plasma polymerization method, described in JP-A No. 2004-68143.

Examples of opaque support substrates include metal plates such aluminum or stainless steel, films, opaque resin substrates, and ceramic substrates.

The external extraction efficiency of light emitted by the organic EL element of the present invention is preferably at least 1% at room temperature, but is more preferably at least 5%.

External extraction quantum yield (%)=(the number of photons emitted by the organic EL element to the exterior/the number of electrons fed to organic EL element)×100

Further, even by simultaneously employing color hue improving filters such as a color filter, simultaneously employed may be color conversion filters which convert emitted light color from the organic EL element to multicolor by employing fluorescent materials. When the color conversion filters are employed, it is preferable that λ max of light emitted by the organic EL element is 480 nm or less.

### <Sealing>

As sealing means employed in the present invention, listed may be, for example, a method in which sealing members, electrodes, and a supporting substrate are subjected to adhesion via adhesives.

The sealing members may be arranged to cover the display region of an organic EL element, and may be an engraved plate or a flat plate. Neither transparency nor electrical insulation is limited.

Specifically listed are glass plates, polymer plate-films, metal plates, and films. Specifically, it is possible to list, as glass plates, soda-lime glass, barium-strontium containing glass, lead glass, aluminosilicate glass, borosilicate glass, barium borosilicate glass, and quartz. Further, listed as polymer plates may be polycarbonate, acryl, polyethylene terephthalate, polyether sulfide, and polysulfone. As a metal plate, listed are those composed of at least one metal selected from the group consisting of stainless steel, iron, copper, aluminum magnesium, nickel, zinc, chromium, titanium, molybdenum, silicon, germanium, and tantalum, or alloys thereof.

In the present invention, since it is possible to convert the element to a thin film, it is possible to preferably employ a metal film. Further, the oxygen permeability of the polymer film is preferably at most 1×10⁻³ cm³/(m²·24 h·MPa), determined by the method based on JIS K 7126-1987, while its water vapor permeability (at 25±0.5° C. and relative humidity (90±2) %) is at most 1×10⁻³ g/(m²·24 h), determined by the method based on JIS K 7129-1992.

Conversion of the sealing member into concave is carried out employing a sand blast process or a chemical etching process.

In practice, as adhesives, listed may be photo-curing and heat-curing types having a reactive vinyl group of acrylic acid based oligomers and methacrylic acid, as well as moisture curing types such as 2-cyanoacrylates. Further listed may be thermal and chemical curing types (mixtures of two liquids) such as epoxy based ones. Still further listed may be hot-melt type polyamides, polyesters, and polyolefins. Yet further listed may be cationically curable type ultraviolet radiation curable type epoxy resin adhesives.

In addition, since an organic EL element is occasionally deteriorated via a thermal process, those are preferred which enable adhesion and curing between room temperature and 80° C. Further, desiccating agents may be dispersed into the aforesaid adhesives. Adhesives may be applied onto sealing portions via a commercial dispenser or printed on the same in the same manner as screen printing.

Further, it is appropriate that on the outside of the aforesaid electrode which interposes the organic layer and faces the support substrate, the aforesaid electrode and organic layer are covered, and in the form of contact with the support substrate, inorganic and organic material layers are formed as a sealing film.

In this case, as materials forming the aforesaid film may be those which exhibit functions to retard penetration of those such as moisture or oxygen which results in deterioration. For example, it is possible to employ silicon oxide, silicon dioxide, and silicon nitride.

Still further, in order to improve brittleness of the aforesaid film, it is preferable that a laminated layer structure is formed, which is composed of these inorganic layers and layers composed of organic materials. Methods to form these films are not particularly limited. It is possible to employ, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a thermal CVD method, and a coating method.

In a gas phase and a liquid phase, it is preferable to inject inert gases such as nitrogen or argon, and inactive liquids such as fluorinated hydrocarbon or silicone oil into the space between the sealing member and the surface region of the organic EL element. Further, it is possible to form vacuum. Still further, it is possible to enclose hygroscopic compounds in the interior.

Examples of hygroscopic compounds include metal oxides (for example, sodium oxide, potassium oxide, calcium oxide, barium oxide, magnesium oxide, and aluminum oxide); sulfates (for example, sodium sulfate, calcium sulfate, magnesium sulfate, and cobalt sulfate); metal halides (for example, calcium chloride, magnesium chloride, cesium fluoride, tantalum fluoride, cerium bromide, magnesium bromide, barium iodide, and magnesium iodide); perchlorates (for example, barium perchlorate and magnesium perchlorate). In sulfates, metal halides, and perchlorates, suitably employed are anhydrides.

### <Protective Film and Protective Plate>

The aforesaid sealing film on the side which nips the organic layer and faces the support substrate or on the outside of the aforesaid sealing film, a protective or a protective plate may be arranged to enhance the mechanical strength of the element.

Specifically, when sealing is achieved via the aforesaid sealing film, the resulting mechanical strength is not always high enough, whereby it is preferable to arrange the protective film or the protective plate described above.

Usable materials for these include glass plates, polymer plate-films, and metal plate-films which are similar to those employed for the aforesaid sealing. However, in terms of light weight and a decrease in thickness, it is preferable to employ polymer films

### <Light Extraction>

It is generally known that an organic EL element emits light in the interior of the layer exhibiting the refractive index (being about 1.7 to about 2.1) which is greater than that of air, whereby only about 15 to about 20% of light generated in the light emitting layer is extracted.

This is due to the fact that light incident to an interface (being an interface of a transparent substrate to air) at an angle of θ which is at least critical angle is not extracted to the exterior of the element due to the resulting total reflection, or light is totally reflected between the transparent electrode or the light emitting layer and the transparent substrate, and light is guided via the transparent electrode or the light emitting layer, whereby light escapes in the direction of the element side surface.

Means to enhance the efficiency of the aforesaid light extraction include, for example, a method in which roughness is formed on the surface of a transparent substrate, whereby total reflection is minimized at the interface of the transparent substrate to air (U.S. Pat. No. 4,774,435), a method in which efficiency is enhanced in such a manner that a substrate results in light collection (JP-A No. 63-314795), a method in which a reflection surface is formed on the side of the element (JP-A No. 1-220394), a method in which a flat layer of a middle refractive index is introduced between the substrate and the light emitting body and an antireflection film is formed (JP-A No. 62-172691), a method in which a flat layer of a refractive index which is equal to or less than the substrate is introduced between the substrate and the light emitting body (JP-A No. 2001-202827), and a method in which a diffraction grating is formed between the substrate and any of the layers such as the transparent electrode layer or the light emitting layer (including between the substrate and the outside) (JP-A No. 11-283751).

In the present invention, it is possible to employ these methods while combined with the organic EL element of the present invention. Of these, it is possible to appropriately employ the method in which a flat layer of a refractive index which is equal to or less than the substrate is introduced between the substrate and the light emitting body and the method in which a diffraction grating is formed between the substrate and any of the layers such as the transparent electrode layer or the light emitting layer (including between the substrate and the outside).

By combining these means, the present invention enables the production of elements which exhibit higher luminance or excel in durability.

When a low refractive index medium of a thickness, which is greater than the wavelength of light, is formed between the transparent electrode and the transparent substrate, the extraction efficiency of light emitted from the transparent electrode to the exterior increases as the refractive index of the medium decreases.

As materials of the low refractive index layer, listed are, for example, aerogel, porous silica, magnesium fluoride, and fluorine based polymers. Since the refractive index of the transparent substrate is commonly about 1.5 to about 1.7, the refractive index of the low refractive index layer is preferably at most approximately 1.5, but is more preferably at most 1.35.

Further, thickness of the low refractive index medium is preferably at least two times the wavelength in the medium. The reason is that when the thickness of the low refractive index medium reaches nearly the wavelength of light so that electromagnetic waves oozed via evernescent enter into the substrate, effects of the low refractive index layer are lowered.

The method in which the interface which results in total reflection or a diffraction grating is introduced in any of the media is characterized in that light extraction efficiency is significantly enhanced.

The above method works as follows. By utilizing properties of the diffraction grating capable of changing the light direction to the specific direction different from diffraction via so-called Bragg diffraction such as primary diffraction or secondary diffraction of the diffraction grating, of light emitted from the light emitting layer, light, which is not emitted to the exterior due to total reflection between layers, is diffracted via introduction of a diffraction grating between any layers or in a medium (in the transparent substrate and the transparent electrode) so that light is extracted to the exterior.

It is preferable that the introduced diffraction grating exhibits a two-dimensional periodic refractive index. The reason is as follows. Since light emitted in the light emitting layer is randomly generated to all directions, in a common one-dimensional diffraction grating exhibiting a periodic refractive index distribution only in a certain direction, light which travels to the specific direction is only diffracted, whereby light extraction efficiency is not sufficiently enhanced.

However, by changing the refractive index distribution to a two-dimensional one, light, which travels to all directions, is diffracted, whereby the light extraction efficiency is enhanced.

As noted above, a position to introduce a diffraction grating may be between any layers or in a medium (in a transparent substrate or a transparent electrode). However, a position near the organic light emitting layer, where light is generated, is desirous.

In this case, the cycle of the diffraction grating is preferably about ½ to about 3 times the wavelength of light in the medium.

The preferable arrangement of the diffraction grating is such that the arrangement is two-dimensionally repeated in the form of a square lattice, a triangular lattice, or a honeycomb lattice.

### <Light Collection Sheet>

Via a process to arrange a structure such as a micro-lens array shape on the light extraction side of the organic EL element of the present invention or via combination with a so-called light collection sheet, light is collected in the specific direction such as the front direction with respect to the light emitting element surface, whereby it is possible to enhance luminance in the specific direction.

In an example of the micro-lens array, square pyramids to realize a side length of 30 μm and an apex angle of 90 degrees are two-dimensionally arranged on the light extraction side of the substrate. The side length is preferably 10 μm to 100 μm. When it is less than the lower limit, coloration results due to generation of diffraction effects, while when it exceeds the upper limit, the thickness increases undesirably.

It is possible to employ, as a light collection sheet, for example, one which is put into practical use in the LED backlight of liquid crystal display devices. It is possible to employ, as such a sheet, for example, the luminance enhancing film (BEF), produced by Sumitomo 3M Limited. As shapes of a prism sheet employed may be, for example, Δ shaped stripes of an apex angle of 90 degrees and a pitch of 50 μm formed on a base material, a shape in which the apex angle is rounded, a shape in which the pitch is randomly changed, and other shapes.

Further, in order to control the light radiation angle from the light emitting element, simultaneously employed may be a light diffusion plate-film For example, it is possible to employ the diffusion film (LIGHT-UP), produced by Kimoto Co., Ltd.

### <Preparation Method of Organic EL Element>

As one example of the preparation method of the organic EL element of the present invention, the preparation method of the organic EL element composed of anode/positive hole injection layer/positive hole transport layer/light emitting layer/electron transport layer/electron injection layer/cathode will be described.

Initially, a thin film composed of desired electrode substances, for example, anode substances is formed on an appropriate base material to reach a thickness of at most 1 μm but preferably 10 nm to 200 nm, employing a method such as vapor deposition or sputtering, whereby an anode is prepared.

Subsequently, on the above, formed are organic compound thin layers including a positive hole injection layer, a positive hole transport layer, a light emitting layer, a positive hole inhibition layer, an electron transport layer, and an electron injection layer, which are organic EL element materials.

Methods to form each of these layers include, as described above, a vapor deposition method and a wet process (a spin coating method, a casting method, an ink-jet method, and a printing method). In the present invention, in view of easy formation of a homogeneous film and rare formation of pin holes, preferred is film formation via the coating method such as the spin coating method, the ink-jet method, or the printing method.

As a more preferable embodiment, it is preferable that three or more organic compound layers are prepared with a wet process

As liquid media which are employed to dissolve or disperse organic metal complexes according to the present invention, employed may be, for example, ketones such as methyl ethyl ketone or cyclohexanone, fatty acid esters such as ethyl acetate, halogenated hydrocarbons such as dichlorobenzene, aromatic hydrocarbons such as toluene, xylene, mesitylene, and cyclohexylbenzene, aliphatic hydrocarbons such as cyclohexane, decaline, and dodecane, and organic solvents such as DMF or DMSO. Further, with regard to dispersion methods, it is possible to achieve dispersion employing dispersion methods such as ultrasonic waves, high shearing force dispersion or media dispersion.

After forming these layers, a thin layer composed of cathode materials is formed on the above layers via a method such as vapor deposition or sputtering so that the film thickness reaches at most 1 μm, but is preferably in the range of 50 nm to 200 nm, whereby a cathode is arranged, and the desired organic EL element is prepared.

Further, by reversing the preparation order, it is possible to achieve preparation in order of a cathode, an electron injection layer, an electron transport layer, a light emitting layer, a positive hole transport layer, a positive hole injection layer, and an anode. When direct current voltage is applied to the multicolor display device prepared as above, the anode is employed as + polarity, while the cathode is employed as − polarity. When 2-40 V is applied, it is possible to observe light emission. Further, alternating current voltage may be applied. The wave form of applied alternating current voltage is not specified.

### <Application>

It is possible to employ the organic EL element of the present invention as display devices, displays, and various types of light emitting sources.

Examples of light emitting sources include, but are not limited to lighting apparatuses (home lighting and car lighting), clocks, backlights for liquid crystals, sign advertisements, signals, light sources of light memory media, light sources of electrophotographic copiers, light sources of light communication processors, and light sources of light sensors.

It is effectively employed especially as backlights of liquid crystal display devices and lighting sources.

If needed, the organic EL element of the present invention may undergo patterning via a metal mask or an ink-jet printing method during film formation.

When the patterning is carried out, only an electrode may undergo patterning, an electrode and a light emitting layer may undergo patterning, or all element layers may undergo patterning. During preparation of the element, it is possible to employ conventional methods.

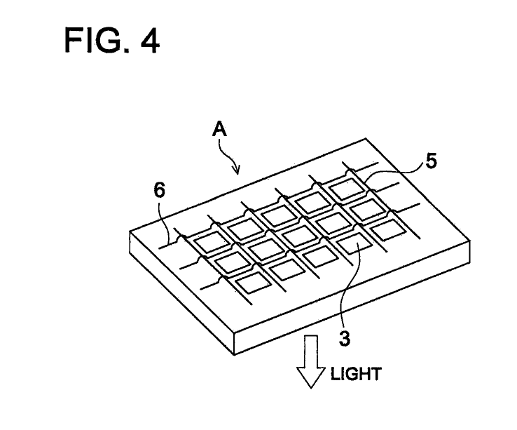

Color of light emitted by the organic EL element of the present invention and compounds according to the present invention is specified as follows. In FIG. 4.16 on page 108 of “Shinpen Shikisai Kagaku Handbook (New Edition Color Science Handbook)” (edited by The Color Science Association of Japan, Tokyo Daigaku Shuppan Kai, 1985), values determined via a spectroradiometric luminance meter CS-1000 (produced by Konica Minolta Sensing Inc.) are applied to the CIE chromaticity coordinate, whereby the color is specified.

Further, when the organic EL element of the present invention is a white element, “white”, as described herein, means that when 2-degree viewing angle front luminance is determined via the aforesaid method, chromaticity at 1,000 cd/m² in the CIE 1931 Color Specification System is within the region of X=0.33±0.07 and Y=0.33±0.1.

### EXAMPLES

The present invention will now be described with reference to examples, however the present invention is not limited thereto. The chemical structures of the compounds used in Examples are shown in the followings. The indication of “%” is used in Examples. Unless specifically notice, this indicates “mass %”.

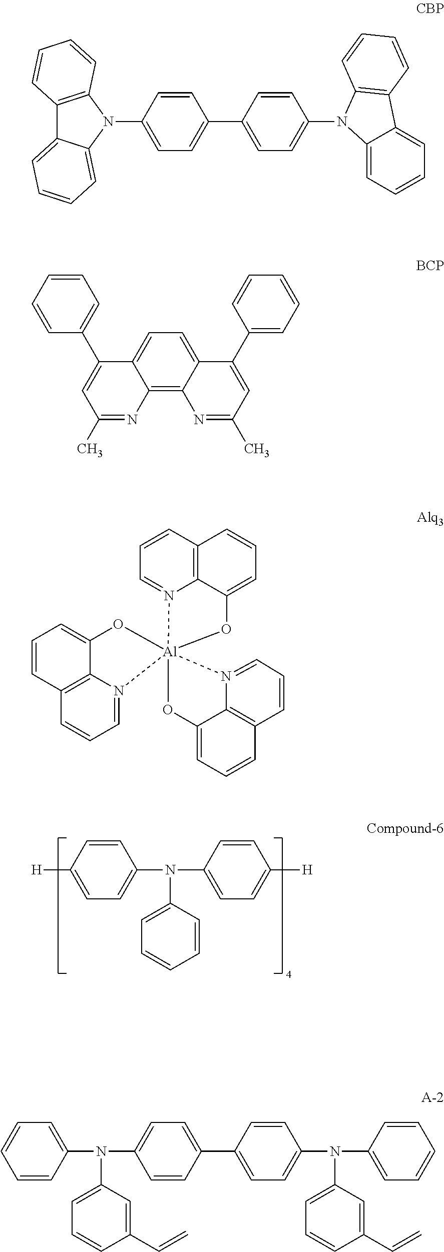

### Example 1

### <Preparation of Organic EL Element 1-1>

An anode was prepared by making patterning to a glass substrate (NA45 produced by NH Techno Glass Corp.) on which a 150 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes. The aforesaid substrate was transferred under an atmosphere of nitrogen, and a solution containing 60 mg of Compound 50a dissolved in 6 ml of toluene was applied by using a spin coating method at 1,000 rpm for 30 seconds to form a film. The film was heated under a vacuum condition at 150° C. for 1 hour to form a positive hole transport layer having a thickness of 30 nm.

Then, the resulting transparent support substrate was fixed to the substrate holder of a commercial vacuum deposition apparatus. Separately, CBP, D-9, BCP and Alq₃ were each respectively placed in 5 tantalum resistance heating boats, and they were fitted in the vacuum deposition apparatus (1^{st} vacuum tank). Further, lithium fluoride was placed in a tantalum resistance heating boat, and aluminium was placed in a molybdenum resistance heating boat, and they were fitted in a 2^{nd} vacuum tank of the vacuum deposition apparatus.

First, the aforesaid heating boat containing CBP and the heating boat containing D-9 were each independently heated via application of electric current by adjusting the deposition speed so that the deposition rate of the emitting host CBP and that of the emitting dopant D-9 became to be 100:6, and deposition was carried out to obtain a light emitting layer having a thickness of 30 nm.

Subsequently, the aforesaid heating boat containing BCP was heated via application of electric current at a deposition rate of 0.1 to 0.2 nm/second, whereby a 1^{st} electron transport layer having a thickness of 10 nm was provided. Further, the aforesaid heating boat containing Alq₃ was heated via application of electric current at a deposition rate of 0.1 to 0.2 nm/second, whereby a 2^{nd} electron transport layer having a thickness of 20 nm was provided.

Next, after transferring the element which had formed to the 2^{nd} electron transport layer into the 2^{nd} vacuum tank with keeping a vacuum condition, a rectangular-holes mask made of stainless steel was placed on the electron transport layer by remote control from the outside of the apparatus. After reducing the pressure of the 2^{nd} vacuum tank to 2×10⁻⁴ Pa, the aforesaid heating boat containing lithium fluoride was heated via application of electric current and deposition was carried out at an evaporation rate of 0.01 to 0.02 nm/second, whereby a cathode buffer layer having a thickness of 0.5 nm was provided. Subsequently, the heating boat containing aluminium was heated via application of electric current and deposition was carried out at an evaporation rate of 1 to 2 nm/second, whereby a cathode having a thickness of 150 nm was provided, and thus Organic EL element 1-1 was prepared.

### <Preparation of Organic EL Elements 1-2 to 1-4>

Organic EL elements 1-2 to 1-4 each were prepared in the same manner as preparation of Organic EL element 1-1 except that the positive hole transport material was changed as described in Table 1.

### <Evaluation of Organic EL Elements>

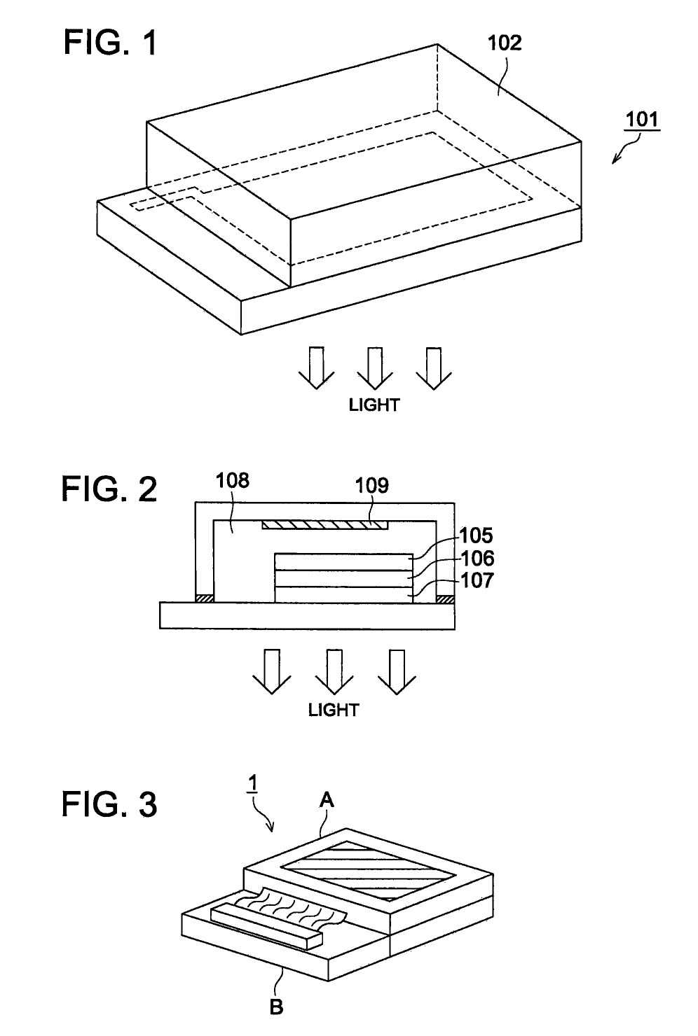

Evaluations of Organic EL elements 1-1 to 1-4 were carried out as follows. The non-light emitting surface of the prepared organic EL element was covered with a glass case, and a 300 μm thick glass substrate was employed as a sealing substrate. An epoxy based light curable type adhesive (LUXTRACK LC0629B produced by Toagosei Co., Ltd.) was employed in the periphery as a sealing material. The resulting one was superimposed on the aforesaid cathode to be brought into close contact with the aforesaid transparent support substrate, and curing and sealing were carried out via exposure of UV radiation onto the glass substrate side, whereby the lighting device shown in FIGS. 1 and 2 was formed.

FIG. 1 is a schematic view of a lighting device and Organic EL element 101 is covered with glass cover 102 (incidentally, sealing by the glass cover was carried out in a globe box under nitrogen ambience (under an ambience of high purity nitrogen gas at a purity of at least 99.999%) so that Organic EL Element 101 was not brought into contact with atmosphere. FIG. 2 is a cross-sectional view of a lighting device, and in FIG. 2, 105 represents a cathode, 106 represents an organic EL layer, and 107 represents a glass substrate fitted with a transparent electrode. Further, the interior of glass cover 102 is filled with nitrogen gas 108 and water catching agent 109 is provided.

### (External Extraction Quantum Efficiency)

Each organic EL element was allowed to emit a light with a constant electric current of 2.5 mA/cm² at room temperature (at about 23° C. to 25° C.). The external extraction quantum efficiency (η) was determined by measuring the luminance (L) (cd/m²) measured immediately after starting to emit light.

The measurement of luminance was done with a spectroradiometric luminance meter CS-1000 (produced by Konica Minolta Sensing Inc.). The external extraction quantum efficiency was represented by the relative value when the external extraction quantum efficiency of Organic EL element 1-1 was set to be 100.

### (Emission Lifetime and Increasing Ratio of Voltage)

Organic EL element was driven with a constant electric current of 2.5 mA/cm² at room temperature to continuously emit a light. The time required for a decease in one half of the luminance of immediately after the initiation of light emission (being the initial luminance) was determined, and the resulting value was employed as an index of the lifetime in terms of a half lifetime (τ_{1/2}). The emission lifetime was represented as a relative value when the lifetime of Organic EL element 1-1 was set to be 100.

Further, the voltage value when the luminance was decreased to one half of the initial luminance was compared with the initial voltage value when the organic EL element was turned on. The increasing ratio was designated as an increasing ratio of voltage, and it was represented as a relative value when the increasing ratio of voltage of Organic EL element 1-1 was set to be 100.

The obtained results are shown in Table 1.

TABLE 1

| Organic | Positive hole | | | Increasing |
|---|---|---|---|---|
| EL ele- | transport | External extraction | Emission | ratio of |
| ment No. | material | quantum efficiency | lifetime | voltage |
| 1-1 | 50a | 100 | 100 | 100 |
| 1-2 | 50b | 109 | 125 | 42 |
| 1-3 | 50c | 121 | 162 | 14 |
| 1-4 | 50d | 130 | 230 | 8 |

Organic EL element 1-1 which was prepared by using a positive hole transport material 50a (weight average molecular weight: 5,000) of the present invention was shown to be excellent in all aspects of external extraction quantum efficiency, emission lifetime, and increasing ratio of voltage.

Further, as are shown in Table 1, Organic EL elements 1-1 to 1-4 which was prepared by using a hole transporting material of the present invention shows excellent properties of all aspects of external extraction quantum efficiency, emission lifetime, and increasing ratio of voltage. However, it was found that Organic EL elements prepared by using a hole transporting material having a weight average molecular weight in the range of 50,000 to 500,000 (50b, 50c, and 50d) achieved fairly improved properties of longer emitting lifetime and larger decrease of increasing ratio of voltage compared with Organic EL element prepared by using Compound 50a having a weight average molecular weight of 5,000.

### Example 2

### <Preparation of Organic EL Element 2-1>

An anode was prepared by making patterning to a glass substrate (NA45 produced by NH Techno Glass Corp.) on which a 150 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

The aforesaid substrate was transferred under an atmosphere of nitrogen, and a solution containing 60 mg of Compound 50a dissolved in 6 ml of toluene was applied by using a spin coating method at 1,000 rpm for 30 seconds to form a film. The film was heated under a vacuum condition at 150° C. for 1 hour to form a positive hole transport layer having a thickness of 30 nm.

Subsequently, a solution containing 60 mg of Host-25 and 6.0 mg of D-6 dissolved in 6 ml of toluene was applied on the positive hole transport layer by using a spin coating method at 1,000 rpm for 30 seconds to form a film. The film was heated under a vacuum condition at 150° C. for 1 hour to form a light emitting layer having a thickness of 40 nm. Further, a solution containing 20 mg of Host-19 dissolved in 6 ml of butanol was applied by using a spin coating method at 1,000 rpm for 30 seconds to form a film. The film was heated under a vacuum condition at 100° C. for 1 hour to form a 1^{st} electron transport layer having a thickness of 20 nm.

Then, this substrate was fixed to the substrate holder of a vacuum deposition apparatus, and 200 mg of Alq₃ was placed in a molybdenum resistance heating boat, and it was fitted in the vacuum deposition apparatus. Subsequently, after reducing the pressure of the vacuum tank to 4×10⁻⁴ Pa, the aforesaid heating boat containing Alq₃ was heated via application of electric current and deposition was carried out onto the aforesaid 1^{st} electron transport layer at a deposition rate of 0.1 nm/second, whereby a 2^{nd} electron transport layer having a thickness of 40 nm was provided. Here, the temperature of the substrate during the deposition was room temperature. Subsequently, 0.5 nm thick lithium fluoride and 110 nm thick aluminum were deposited to form a cathode, whereby Organic EL element 2-1 was prepared.

### <Preparation of Organic EL Elements 2-2 to 2-4>

Organic EL elements 2-2 to 2-4 each were prepared in the same manner as preparation of Organic EL element 2-1 except that the positive hole transport material was changed as described in Table 2.

### <Evaluation of Organic EL Elements>

Evaluations of Organic EL elements 2-1 to 2-4 were carried out in the same manner as evaluations in Example 1. The external extraction quantum efficiency and the emission lifetime were represented by the relative value when the external extraction quantum efficiency and the emission lifetime of Organic EL element 2-1 were set to be 100.

The obtained results are shown in Table 2.

TABLE 2

| Organic | Positive hole | | | Increasing |
|---|---|---|---|---|
| EL ele- | transport | External extraction | Emission | ratio of |
| ment No. | material | quantum efficiency | lifetime | voltage |
| 2-1 | 50a | 100 | 100 | 100 |
| 2-2 | 50b | 108 | 210 | 34 |
| 2-3 | 50c | 123 | 320 | 12 |
| 2-4 | 50d | 140 | 392 | 7 |

Organic EL element 2-1 which was prepared by using a positive hole transport material 50a of the present invention and a phosphorescence dopant D-26 of the present invention was shown to be excellent in all aspects of external extraction quantum efficiency, emission lifetime, and increasing ratio of voltage compared with Organic EL element 1-1 in Example 1.

Further, it was found from Table 2 that Organic EL elements prepared by using a hole transporting material having a weight average molecular weight in the range of 50,000 to 500,000 (50b, 50c, and 50d) achieved fairly improved properties of longer emitting lifetime and larger decrease of increasing ratio of voltage compared with Organic EL element 2-1 prepared by using Compound 50a having a weight average molecular weight of 5,000.

### Example 3

### <Preparation of Full Color Display Device>

### (Blue Light Emitting Element)

Organic EL element 2-4 of Example 2 was used as a blue light emitting element.

### (Green Light Emitting Element)

A green light emitting element was prepared in the same manner as preparation of Organic EL element 1-4 of Example 1, except that D-9 was replaced with D-1. And this element was used as a green light emitting element.

### (Red Light Emitting Element)

A red light emitting element was prepared in the same manner as preparation of Organic EL element 1-4 of Example 1, except that D-9 was replaced with D-6. And this element was used as a red light emitting element.

Thus prepared red, green and blue light emitting organic EL elements were placed in juxtaposition with each other on the same substrate to form an active matrix mode full color display device having a form as indicated in FIG. 3. Only a schematic drawing of display section A in the prepared display device was shown in FIG. 4. Namely, a display section A is provided with such as a wiring part, which contains plural scanning lines 5 and data lines 6, and plural pixels 3 (pixel emitting a light in the red region, pixel emitting a light in the green region, and pixel emitting a light in the blue region) on a substrate. Scanning lines 5 and plural data lines 6 in a wiring part each are comprised of a conductive material, and scanning lines 5 and data lines 6 are perpendicular in a grid form and are connected to pixels 3 at the right-angled crossing points (details are not shown in the drawing). The aforesaid plural pixels 3 in organic EL element each correspond to each emitting color and they are driven with an active matrix mode in which a switching transistor and a driving transistor are provided as an active element. Pixel 3 receives an image data from data line 6 when a scanning signal is applied from scanning line 5 and emits according to the received image data. Full-color display device was prepared by appropriately arranging pixels having an emission color in a red region, pixels in a green region and pixels in a blue region, side by side on the same substrate.

The prepared full-color display device was proved to exhibit high luminance and high durability, and to reproduce a vivid full-color moving image.

### Example 4

### <Preparation of White Light Emitting Organic EL Element and White Light Lighting Device>

An anode was prepared by making patterning to a glass substrate of 100 mm×100 mm×1.1 mm (NA45 produced by NH Techno Glass Corp.) on which a 100 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

The aforesaid substrate was transferred under an atmosphere of nitrogen, and a solution containing 60 mg of Compound 50d dissolved in 6 ml of toluene was applied by using a spin coating method at 1,000 rpm for 30 seconds to form a film The film was heated under a vacuum condition at 150° C. for 100 seconds to form a positive hole transport layer having a thickness of 30 nm.

Then, one the positive hole transport layer was applied a solution containing 20 mg of CBP, 0.5 mg of Compound D-6 and 5.0 mg of Compound D-26 dissolved in 6 ml of toluene by using a spin coating method at 1,000 rpm for 30 seconds to form a film. The film was heated under a vacuum condition at 150° C. for one hour to obtain a light emitting layer.

One the light emitting layer was applied a solution containing 30 mg of BCP dissolved in 6 ml of butanol by using a spin coating method at 1,000 rpm for 30 seconds to form a film. The film was heated under a vacuum condition at 80° C. for one hour to obtain a 1^{st} electron transport layer.

Subsequently, the substrate was fixed to the substrate holder of the vacuum deposition apparatus, and 200 mg of Alq₃ was placed in a molybdenum resistance heating boat and was fixed to the vacuum deposition apparatus. After the pressure of the vacuum tank was reduced to 4×10⁻⁴ Pa, the aforesaid heating boat including Alq₃ was heated via application of electric current and deposition was carried out onto the aforesaid 1^{st} electron transport layer at an evaporation rate of 0.1 nm/second, whereby a 2^{nd} electron transport layer having a thickness of 40 nm was further arranged.

Here, the temperature of the substrate during the deposition was room temperature.

Subsequently, 0.5 nm thick potassium fluoride was deposited, then 110 nm thick aluminum was deposited to form a cathode, whereby a white light emitting organic EL element was prepared.

When the prepared Organic EL element was supplied with electric current, an almost white light was obtained, and it was revealed that this organic EL element can be used as a lighting device.

### Example 5

### <Preparation of Organic EL Element 5-1>

An anode was prepared by making patterning to a glass substrate (NA45 produced by NH Techno Glass Corp.) on which a 150 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

The aforesaid substrate was transferred under an atmosphere of nitrogen, and a solution containing 60 mg of Compound 62 dissolved in 6 ml of toluene was applied by using a spin coating method at 1,000 rpm for 30 seconds to form a film. The film was heated under a vacuum condition at 150° C. for 1 hour to form a positive hole transport layer having a thickness of 30 nm.

Subsequently, a solution containing 60 mg of Host-25 and 6.0 mg of D-6 dissolved in 6 ml of toluene was applied on the positive hole transport layer by using a spin coating method at 1,000 rpm for 30 seconds to form a film The film was heated under a vacuum condition at 150° C. for 1 hour to form a light emitting layer having a thickness of 40 nm.

Further, a solution containing 20 mg of Host-19 dissolved in 6 ml of butanol was applied by using a spin coating method at 1,000 rpm for 30 seconds to form a film. The film was heated under a vacuum condition at 100° C. for 1 hour to form a 1^{st} electron transport layer having a thickness of 20 nm.

Then, this substrate was fixed to the substrate holder of a vacuum deposition apparatus, and 200 mg of Alq₃ was placed in a molybdenum resistance heating boat, and it was fitted in the vacuum deposition apparatus.

Subsequently, after reducing the pressure of the vacuum tank to 4×10⁻⁴ Pa, the aforesaid heating boat containing Alq₃ was heated via application of electric current and deposition was carried out onto the aforesaid 1^{st} electron transport layer at a deposition rate of 0.1 nm/second, whereby a 2^{nd} electron transport layer having a thickness of 40 nm was provided.

Here, the temperature of the substrate during the deposition was room temperature. Subsequently, 0.5 nm thick potassium fluoride was deposited, then 110 nm thick aluminum was deposited to form a cathode, whereby Organic EL element 5-1 was prepared.

### <Preparation of Organic EL Elements 5-2>

Organic EL elements 5-2 was prepared in the same manner as preparation of Organic EL element 5-1 except that Compound 62 was replaced with Compound 62Br.

### <Measurement of Halogen Content in Positive Hole Transport Material>

With respect to Compound 62 and Compound 62Br each respectively used in Organic EL element 5-1 and Organic EL element 5-2, the existence of end-cap treatment was confirmed by the measurement of halogen content ratio.

The measurement of halogen content ratio in Compound 62Br and Compound 62 was carried out with an Inductively Coupled Plasma Mass Spectroscopy (ICP-MS) (using an apparatus SPQ9700 made by SII Nano Technology Co., Ltd.). The measured halogen content ratios were shown in Table 3.

### <Evaluation of Organic EL Elements>

Evaluations of Organic EL elements 5-1 and 5-2 were carried out in the same manner as evaluations in Example 1. The external extraction quantum efficiency and the emission lifetime were represented by the relative value when the external extraction quantum efficiency and the emission lifetime of Organic EL element 5-1 were set to be 100.

The obtained results are shown in Table 3.

TABLE 3

| Organic | Positive hole transport | | External | | | |
|---|---|---|---|---|---|---|
| EL | material | | extraction | | | |
| element | | Existence of | quantum | Emission | Br content | |
| No. | Compound | end-cap | efficiency | lifetime | ratio | Remarks |
| 5-1 | 62 | Yes | 100 | 100 | 82 ppm | Invention |
| 5-2 | 62Br | None | 82 | 8.2 | 1430 ppm | Comparison |

It is clear the followings from Table 3. Organic EL element 5-1 of the present invention prepared by subjected to end-cap treatment exhibited substantial improvement in light emitting efficiency and emission lifetime compared with comparative Organic EL element 5-2 prepared by using a positive hole transport material 62Br without being subjected to end-cap treatment.

### Example 6

As described below, Organic EL elements 5-3 and 5-4 were prepared as comparative element of Organic EL elements 5-1 in Example 5. In addition, Organic EL elements 5-1 was prepared in the same way as Example 5.

### <Preparation of Organic EL Element 5-3>

An anode was prepared by making patterning to a glass substrate (NA45 produced by NH Techno Glass Corp.) on which a 150 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

The aforesaid substrate was transferred under an atmosphere of nitrogen, and a solution containing 60 mg of Compound 6 (described in WO 02/094965) dissolved in 6 ml of toluene was applied by using a spin coating method at 1,000 rpm for 30 seconds to form a film. The film was heated under a vacuum condition at 150° C. for 1 hour to form a positive hole transport layer having a thickness of 30 nm.

Subsequently, a solution containing 60 mg of Host-25 and 6.0 mg of D-6 dissolved in 6 ml of toluene was applied on the positive hole transport layer by using a spin coating method at 1,000 rpm for 30 seconds to form a film. The film was heated under a vacuum condition at 150° C. for 1 hour to form a light emitting layer having a thickness of 40 nm.

Further, a solution containing 20 mg of Host-19 dissolved in 6 ml of butanol was applied by using a spin coating method at 1,000 rpm for 30 seconds to form a film. The film was heated under a vacuum condition at 100° C. for 1 hour to form a 1^{st} electron transport layer having a thickness of 20 nm.

Next, this substrate was fixed to the substrate holder of a vacuum deposition apparatus, and 200 mg of Alq₃ was placed in a molybdenum resistance heating boat, and it was fitted in the vacuum deposition apparatus. Subsequently, after reducing the pressure of the vacuum tank to 4×10⁻⁴ Pa, the aforesaid heating boat containing Alq₃ was heated via application of electric current and deposition was carried out onto the aforesaid 1^{st} electron transport layer at a deposition rate of 0.1 nm/second, whereby a 2^{nd} electron transport layer having a thickness of 40 nm was provided.

Here, the temperature of the substrate during the deposition was room temperature. Subsequently, 0.5 nm thick potassium fluoride was deposited, then 110 nm thick aluminum was deposited to form a cathode, whereby Organic EL element 5-3 was prepared.

### <Preparation of Organic EL Element 5-4>

An anode was prepared by making patterning to a glass substrate (NA45 produced by NH Techno Glass Corp.) on which a 150 nm film of ITO (indium tin oxide) was formed. Thereafter, the above transparent support substrate provided with the ITO transparent electrode was subjected to ultrasonic washing with isopropyl alcohol, followed by drying with desiccated nitrogen gas, and was subjected to UV ozone washing for 5 minutes.

The aforesaid substrate was transferred under an atmosphere of nitrogen, and a solution containing 60 mg of Compound A-2 (described in WO 08/090,795) dissolved in 6 ml of toluene was applied by using a spin coating method at 1,000 rpm for 30 seconds to form a film having a thickness of 30 nm. The film was dried under a vacuum condition at 60° C. for 1 hour, followed by irradiating for 5 minutes with UV lights to form a positive hole transport layer.

Subsequently, a solution containing 60 mg of Host-25 and 6.0 mg of D-6 dissolved in 6 ml of toluene was applied on the positive hole transport layer by using a spin coating method at 1,000 rpm for 30 seconds to form a film The film was heated under a vacuum condition at 150° C. for 1 hour to form a light emitting layer having a thickness of 40 nm.

Further, a solution containing 20 mg of Host-19 dissolved in 6 ml of butanol was applied by using a spin coating method at 1,000 rpm for 30 seconds to form a film. The film was heated under a vacuum condition at 100° C. for 1 hour to form a 1^{st} electron transport layer having a thickness of 20 nm.

Then, this substrate was fixed to the substrate holder of a vacuum deposition apparatus, and 200 mg of Alq₃ was placed in a molybdenum resistance heating boat, and it was fitted in the vacuum deposition apparatus. Subsequently, after reducing the pressure of the vacuum tank to 4×10⁻⁴ Pa, the aforesaid heating boat containing Alq₃ was heated via application of electric current and deposition was carried out onto the aforesaid 1^{st} electron transport layer at a deposition rate of 0.1 nm/second, whereby a 2^{nd} electron transport layer having a thickness of 40 nm was provided.

Here, the temperature of the substrate during the deposition was room temperature. Subsequently, 0.5 nm thick potassium fluoride was deposited, then 110 nm thick aluminum was deposited to form a cathode, whereby Organic EL element 5-4 was prepared.

### <Evaluation of Organic EL Elements>

Evaluations of Organic EL elements 5-1, 5-3 and 5-4 were carried out in the same manner as evaluations in Example 1. The external extraction quantum efficiency and the emission lifetime were represented by the relative value when the external extraction quantum efficiency and the emission lifetime of Organic EL element 5-1 were set to be 100.

The obtained results are shown in Table 4.

TABLE 4

| | Positive hole | | | | |
|---|---|---|---|---|---|
| Organic EL | transport | External extraction | Emission | Increasing ratio | |
| element No. | material Compound | quantum efficiency | lifetime | of voltage | Remarks |
| 5-1 | 62 | 100 | 100 | 100 | Invention |
| 5-3 | Compound 6 | 3.2 | 6.5 | 8200 | Comparison |
| 5-4 | A-2 | 83 | 62 | 232 | Comparison |

It is clear from Table 4 that Organic EL element 5-1 of the present invention prepared by using the polymer exhibited fairly high values of light emitting efficiency and emission lifetime compared with comparative Organic EL elements 5-3 and 5-4.

Moreover, it was found that Organic EL element 5-3 did not fully function as a light emitting element because the positive hole transport layer and the light emitting layer thereof were mixed, and that Organic EL element 5-4 received the damage in the positive hole transport layer by UV light irradiation during the formation of the positive hole transport layer, and the properties as an element was deteriorated.

### Example 7

### Dopant Concentration

### <Preparation of Organic EL Elements 7-1 to 7-4>

Organic EL elements 7-1 to 7-4 each were prepared in the same manner as preparation of Organic EL element 5-1 except that the added amount of D-26 was adjusted so that the dopant concentration (mass ratio of the dopant in the light emitting layer) became as described in Table 5.

### <Preparation of Organic EL Elements 7-5 to 7-16>

Organic EL elements 7-5 to 7-16 each were prepared in the same manner as preparation of Organic EL element 5-1 except that the dopant and the dopant concentration were change as described in Table 5.

### <Evaluation of Organic EL Elements>

Evaluations of the obtained Organic EL elements 7-1 to 7-16 were carried out in the same manner as evaluations in Example 1. The external extraction quantum efficiency and the emission lifetime were represented by the relative value when the external extraction quantum efficiency and the emission lifetime of Organic EL element 7-1 were set to be 100.

The obtained results are shown in Table 5.

TABLE 5

| | | | External | | |
|---|---|---|---|---|---|
| Organic | | Dopant | extraction | | |
| EL ele- | Dopant | concen- | quantum | Emission | |
| ment No. | compound | tration % | efficiency | lifetime | Remarks |
| 7-1 | D-26 | 5 | 100 | 100 | Invention |
| 7-2 | D-26 | 10 | 120 | 180 | Invention |
| 7-3 | D-26 | 20 | 163 | 329 | Invention |
| 7-4 | D-26 | 30 | 142 | 288 | Invention |
| 7-5 | D-41 | 5 | 98 | 105 | Invention |
| 7-6 | D-41 | 10 | 121 | 162 | Invention |
| 7-7 | D-41 | 20 | 183 | 181 | Invention |
| 7-8 | D-41 | 30 | 172 | 155 | Invention |
| 7-9 | D-1 | 5 | 63 | 82 | Comparison |
| 7-10 | D-1 | 10 | 42 | 32 | Comparison |
| 7-11 | D-1 | 20 | 5.3 | 7.3 | Comparison |
| 7-12 | D-1 | 30 | 2.1 | 5.1 | Comparison |
| 7-13 | D-9 | 5 | 32 | 21 | Comparison |
| 7-14 | D-9 | 10 | 3.3 | 6.7 | Comparison |
| 7-15 | D-9 | 20 | 1.8 | 0.8 | Comparison |
| 7-16 | D-9 | 30 | 0 | 0 | Comparison |

It is clear the followings from Table 5. Organic EL elements 7-1 to 7-8 of the present invention which were prepared by using a phosphorescence dopant of the present invention exhibited substantial improvement in emission lifetime and light emitting efficiency compared with comparative Organic EL elements 7-9 to 7-12 (using D-1) and comparative Organic EL elements 7-13 to 7-16 (using D-9) prepared by using a conventionally known phosphorescence dopant.

### DESCRIPTION OF SYMBOLS

1: display
3: pixel
5: scanning line
6: data line
A: display section
B: control section
101: organic EL element
102: glass cover
105: cathode
106: organic EL layer
107: glass substrate having a transparent electrode
108: nitrogen gas
109: water catching agent

1. An organic electroluminescence element comprising an anode, a cathode and an organic compound layer sandwiched between the anode and the cathode, provided that the organic compound layer comprises at least a phosphorescence dopant and a polymer which contains a partial structure represented by Formula (1), and a terminal end of the polymer being end-capped,
wherein the phosphorescence dopant is a metal complex containing a ligand composed of a 5 or six membered aromatic hydrocarbon ring or a 5 or six membered aromatic heterocyclic group which is bonded to a five membered nitrogen containing aromatic heterocyclic group: 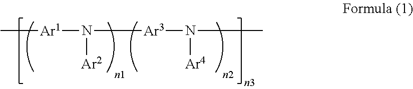
wherein Ar¹ and Ar³ each independently represent an arylene group which may have a substituent, and Ar¹ and Ar³ each may be bonded through a joint group; Ar² and Ar⁴ each independently represent an aryl group or an aromatic heterocyclic group which may have a substituent; n1 and n2 are integer of 0 to 2, provided that n1 and n2 are not simultaneously set to be 0; and n3 is an integer of 10 to 1,000.

2. The organic electroluminescence element of claim 1,
wherein the phosphorescence dopant is a compound represented by Formula (D-1): 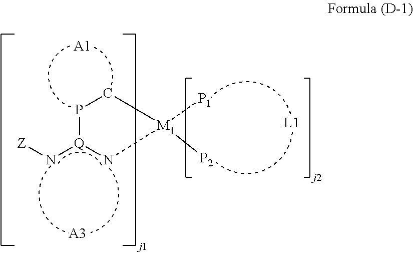
wherein P and Q each represent a carbon atom or a nitrogen atom; A1 represents an atomic group which forms an aromatic hydrocarbon ring or an aromatic heterocyclic group together with P—C; A3 is an atomic group which forms an aromatic heterocyclic group together with N-Q-N; P₁-L1-P₂ represents a bidentate ligand, provided that P₁ and P₂ each independently represent a carbon atom, a nitrogen atom, or an oxygen atom; L1 represents an atomic group which forms a bidentate ligand together with P₁ and P₂; j1 is an integer of 1 to 3, j2 is an integer of 0 to 2, provided that the sum of j1 and j2 is 2 or 3; M₁ represents a transition metal element of Group 8 to Group 10 in the periodic table; and Z represents a substituent.

3. The organic electroluminescence element of claim 1,
wherein the polymer containing the partial structure represented by Formula (1) contains a partial structure represented by Formula (2): 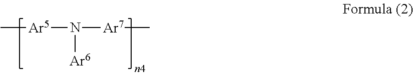
wherein Ar⁵ and Ar⁷ each independently represent an arylene group which may have a substituent; Ar⁶ represents an aryl group or an aromatic heterocyclic group which may have a substituent; and n4 is an integer of 10 to 1,000.

4. The organic electroluminescence element of claim 1,
wherein the polymer containing the partial structure represented by Formula (1) contains a partial structure represented by Formula (3): 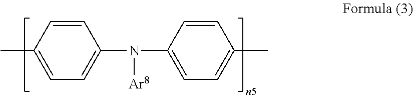
wherein Ar⁸ represents an aryl group or an aromatic heterocyclic group which may have a substituent; and n4 is an integer of 10 to 1,000.

5. The organic electroluminescence element of claim 1,
wherein the polymer containing the partial structure represented by Formula (1) has a weight average molecular weight of 50,000 to 500,000 as a polystyrene conversion value.

6. The organic electroluminescence element of claim 1,
wherein the phosphorescence dopant is a blue phosphorescence dopant.

7. The organic electroluminescence element of claim 1,
wherein at least two organic compound layers are prepared by film making with a wet process.

8. The organic electroluminescence element of claim 1,
wherein the organic electroluminescence element emits a white light.

9. A lighting device comprising the organic electroluminescence element of claim 1.

10. A display device comprising the organic electroluminescence element of claim 1.
